(19) United States
(12) Patent Application Publication
(10) Pub. No.: US 2024/0258482 A1
(43) Pub. Date: Aug. 1, 2024

(54) DISPLAY DEVICE

(71) Applicant: LG Display Co., Ltd., Seoul (KR)

(72) Inventors: Daeyoung SEO, Seoul (KR); Jongsung KIM, Seoul (KR); Yongmin HA, Seoul (KR)

(21) Appl. No.: 18/401,141

(22) Filed: Dec. 29, 2023

(30) Foreign Application Priority Data
Jan. 26, 2023 (KR) 10-2023-0010276

(51) Int. Cl. H01L 33/62; H01L 25/16; H01L 27/12

(52) U.S. Cl. CPC H01L 33/62; H01L 25/167; H01L 27/124

(57) ABSTRACT

In a display device according to an embodiment of the present disclosure, a redundant light-emitting element is disposed on a line substrate separate from a panel unit in which the main light-emitting element is included, thereby reducing occurrence of a defective pixel due to a defective main light-emitting element.

### CROSS-REFERENCE TO RELATED APPLICATION

This application claims priority from Korean Patent Application No. 10-2023-0010276 filed on Jan. 26, 2023 in the Korean Intellectual Property Office, and all the benefits accruing therefrom under 35 U.S.C. 119, the contents of which in its entirety are herein incorporated by reference.

### BACKGROUND

### Technical Field

The present disclosure relates to a display device.

### Description of Related Art

Display devices are implemented in very diverse forms such as televisions, monitors, smart phones, tablet PCs, laptops, and wearable devices.

Among display devices, a light-emitting type display device has a light-emitting element or light source built therein, and can display information using light generated from the built-in light-emitting element or light source.

A display device including a self-light-emitting element may be implemented to be thinner than a display device having a light source built therein, and can be flexible, folded, bent, or rolled.

The display device having the self-light-emitting element may include, for example, an organic light-emitting display device (OLED; Organic Light Emitting Diode Display) including a light-emitting layer made of an organic material, or a micro-LED display device (Micro LED; Micro Light Emitting Diode Display), etc., including a light-emitting layer made of an inorganic material.

The micro-LED display device includes the light-emitting layer made of the inorganic material that is resistant to moisture and oxygen, and thus has excellent reliability and a long lifespan compared to the display device including a light-emitting layer made of an organic material.

Further, a micro-LED element of the micro-LED display device not only lights up quickly, but also consumes smaller power and displays a high-luminance image. Thus, the micro-LED display device is advantageously applied to an extra-large screen.

### BRIEF SUMMARY

The disclosure is related to a display device in which a plurality of panel units are coupled to a line substrate on which a link line is disposed. The micro-LED display device may have a redundancy structure in which two or more light-emitting elements are disposed per one sub-pixel in order to solve the problem of defective pixels occurring during a manufacturing process.

For example, a main light-emitting element and a redundant light-emitting element are disposed in one sub-pixel. Thus, when a defect occurs in the main light-emitting element, light may be emitted from the redundant light-emitting element.

However, in such a redundancy structure, the redundant light-emitting element must be added in addition to the main light-emitting element, such that there is a problem in that the cost related to the light-emitting elements greatly increases at least twice.

When the redundancy structure is not selected, the defective light-emitting element may be repaired through the repair process.

However, during the repair process for repairing the light-emitting element, a thin-film transistor or other stacked layers which have already been completely formed may be damaged.

The inventors of the present disclosure have invented a display device capable of solving the occurrence of the defective light-emitting element while reducing damage to the thin-film transistor as well as reducing a cost due to the increase in the number of the light-emitting elements.

A technical solution according to an embodiment of the present disclosure provides a display device capable of, among others, solving the occurrence of the defective pixel while reducing damage to a thin-film transistor.

Further, a technical solution according to an embodiment of the present disclosure provides a display device capable of solving the occurrence of the defective pixel while reducing an additional cost related to the redundant light-emitting element.

Further, a technical solution according to an embodiment of the present disclosure provides a display device capable of reducing a bezel area such that a boundary between panel units is substantially invisible.

Further, a technical solution according to an embodiment of the present disclosure provides a display device capable of easily implementing a large screen.

Further, a technical solution according to an embodiment of the present disclosure provides a transparent display device with improved transmittance.

The technical features and benefits of the present disclosure are not limited to those above-mentioned. Other technical features, benefits, and advantages of the present disclosure that are not mentioned may be understood based on following descriptions, and may be more clearly understood based on embodiments according to the present disclosure. Further, it will be easily understood that the features and advantages according to the present disclosure may be realized using means shown or implied in the specification or combinations thereof.

A display device according to an embodiment of the present disclosure includes a plurality of panel units, each including a plurality of first light-emitting elements; and a line substrate on which a plurality of second light-emitting elements are disposed, wherein the plurality of panel units are coupled to the line substrate in a tiling manner.

A display device according to an embodiment of the present disclosure includes a line substrate on which a plurality of first light-emitting elements and a plurality of second light-emitting elements are disposed; and a plurality of panel units, each panel unit including a thin-film transistor for applying a driving signal to each of the plurality of first light-emitting elements and each of the plurality of second light-emitting elements, wherein the plurality of panel units are coupled to the line substrate in a tiling manner.

A display device according to still an embodiment of the present disclosure includes a plurality of panel units, wherein each panel unit includes a plurality of signal lines, a plurality of first light-emitting elements, and a thin-film transistor for applying a driving signal to the first light-emitting elements; a line substrate on which a plurality of link lines and a plurality of second light-emitting elements are disposed; and a plurality of first connection members and a plurality of second connection members disposed between the line substrate and the panel units, wherein the first connection member electrically connects the link line and the signal line to each other, wherein the second connection member electrically connects the second light-emitting element and the thin-film transistor to each other.

A display device according to still yet an embodiment of the present disclosure includes a line substrate on which a plurality of link lines, a plurality of first light-emitting elements, and a plurality of second light-emitting elements are disposed; a plurality of panel units, wherein each panel unit includes a plurality of signal lines and a thin-film transistor for applying a driving signal to each of the first light-emitting element and the second light-emitting element; and a plurality of first connection members and a plurality of second connection members disposed between the line substrate and the panel units, wherein the first connection member electrically connects the link line and the signal line to each other, wherein the second connection member electrically connects the first light-emitting element and the second light-emitting element to the thin-film transistor.

According to an embodiment of the present disclosure, the redundant light-emitting element may be disposed on the line substrate separate from the panel unit in which the main light-emitting element is included. Thus, the occurrence of the defective pixel due to the defective main light-emitting element may be removed.

Accordingly, the thin-film transistor in the panel unit may not be affected by the defective pixel repair process. Thus, according to an embodiment of the present disclosure, not only the occurrence of the defective pixel be reduced while reducing damage to the thin-film transistor, but also a display device with improved efficiency, high luminance, and long lifespan may be implemented due to the reduction of the occurrence of the defective pixel.

Further, according to an embodiment of the present disclosure, the main light-emitting element and the redundant light-emitting element may be disposed on the line substrate separate from the panel unit in which the thin-film transistor is included. Thus, the occurrence of the defective pixel due to the defective main light-emitting element may be removed.

Accordingly, the thin-film transistor in the panel unit may not be affected by the defective pixel repair process. Thus, according to an embodiment of the present disclosure, not only the occurrence of the defective pixel be reduced while reducing damage to the thin-film transistor, but also a display device with improved efficiency, high luminance, and long lifespan may be implemented due to the reduction of the occurrence of the defective pixel.

Further, according to an embodiment of the present disclosure, the redundant light-emitting element may be disposed on the line substrate separate from the panel unit where the main light-emitting element is included. Thus, after inspecting whether the main light-emitting element is defective, the redundant light-emitting element may be additionally placed based on the inspection result.

In some implementations, the redundant light-emitting element may be disposed only in the sub-pixel where the defective main light-emitting element is disposed, while the redundant light-emitting element may not be disposed in the sub-pixel where the normal main light-emitting element is disposed. Thus, an unnecessary redundant light-emitting element does not have to be disposed, such that not only may a large cost reduction effect be obtained, but also an effect of process optimization may be obtained.

Further, according to an embodiment of the present disclosure, the main light-emitting element and the redundant light-emitting element may be disposed on the separate line substrate from the panel unit where the thin-film transistor is include. Thus, after inspecting whether the main light-emitting element is defective, a redundant light-emitting element may be additionally disposed based on the inspection result.

In some implementations, the redundant light-emitting element may be disposed only in the sub-pixel where the defective main light-emitting element is disposed, while the redundant light-emitting element is not required to be disposed in the sub-pixel where the normal main light-emitting element is disposed. Thus, an unnecessary redundant light-emitting element does not have to be disposed, such that not only may a large cost reduction effect be obtained, but also a process optimization effect may be obtained.

Further, according to an embodiment of the present disclosure, the plurality of panel units may be coupled to the line substrate in a tiling manner, thereby reducing the bezel area, and thus substantially preventing the boundary between the panel units from being visually recognized.

Further, according to an embodiment of the present disclosure, the plurality of panel units may be coupled to the line substrate in a tiling manner, thereby freely and easily implementing a display device having a large screen of various sizes and shapes.

Further, according to an embodiment of the present disclosure, the plurality of panel units, each including a plurality of signal lines may be disposed on the line substrate on which the plurality of link lines are disposed. In this regard, the link lines and the signal lines may overlap each other. Thus, transmittance of a transparent display device may be improved.

Effects of the present disclosure are not limited to the effects mentioned above, and other effects not mentioned will be clearly understood by those skilled in the art from the descriptions below.

### BRIEF DESCRIPTION OF THE SEVERAL VIEWS OF THE DRAWINGS

FIG. 1 is a schematic plan view of a display device according to an embodiment of the present disclosure.

FIG. 2 is an enlarged plan view of a partial area of a panel unit according to an embodiment of the present disclosure.

FIG. 3 is an enlarged plan view of a partial area of a line substrate according to an embodiment of the present disclosure.

FIG. 4 is an enlarged plan view of a partial area of a panel unit according to an embodiment of the present disclosure.

FIG. 5 is an enlarged plan view of a partial area of a line substrate according to an embodiment of the present disclosure.

FIG. 6, FIG. 7, and FIG. 8 are cross-sectional views of partial areas of FIG. 2 and FIG. 3 in a state in which a line substrate and a panel unit are coupled to each other according to an embodiment of the present disclosure.

FIG. 9 is a detailed cross-sectional view of one sub-pixel in a state in which a line substrate and a panel unit are coupled to each other according to an embodiment of the present disclosure.

FIG. 10 is a circuit diagram of a case where an anode electrode of a line substrate and an anode electrode of a panel unit are electrically connected to each other according to an embodiment of the present disclosure.

FIG. 11 is a detailed cross-sectional view of one sub-pixel in a state in which a line substrate and a panel unit are coupled to each other according to an embodiment of the present disclosure.

FIG. 12 is a circuit diagram of a case where a cathode electrode of a line substrate and a cathode electrode of a panel unit are electrically connected to each other according to an embodiment of the present disclosure.

FIG. 13 is a detailed cross-sectional view of one sub-pixel in a state in which a line substrate and a panel unit are coupled to each other according to an embodiment of the present disclosure.

### DETAILED DESCRIPTION

Advantages and features of the present disclosure, and a method of achieving the advantages and features will become apparent with reference to embodiments described later in detail together with the accompanying drawings. However, the present disclosure is not limited to the embodiments as disclosed below, but may be implemented in various different forms. Thus, these embodiments are set forth only to make the present disclosure complete, and to completely inform the scope of the present disclosure to those of ordinary skill in the technical field to which the present disclosure belongs.

A shape, a size, a ratio, an angle, a number, etc., disclosed in the drawings for describing the embodiments of the present disclosure are illustrative, and the present disclosure is not limited thereto. The same reference numerals refer to the same elements herein. Further, descriptions and details of well-known steps and elements are omitted for simplicity of the description. Furthermore, in the following detailed description of the present disclosure, numerous specific details are set forth in order to provide a thorough understanding of the present disclosure. However, it will be understood that the present disclosure may be practiced without these specific details. In other instances, well-known methods, procedures, components, and circuits have not been described in detail so as not to unnecessarily obscure aspects of the present disclosure.

The terminology used herein is directed to the purpose of describing example embodiments only and is not intended to be limiting of the present disclosure. As used herein, the singular constitutes “a” and “an” are intended to include the plural constitutes as well, unless the context clearly indicates otherwise. It will be further understood that the terms “comprise”, “including”, “include”, and “including” when used in this specification, specify the presence of the stated features, integers, operations, elements, and/or components, but do not preclude the presence or addition of one or more other features, integers, operations, elements, components, and/or portions thereof. As used herein, the term “and/or” includes any and all combinations of one or more of the associated listed items. Expression such as “at least one of” when preceding a list of elements may modify the entire list of elements and may not modify the individual elements of the list. In interpretation of numerical values, an error or tolerance therein may occur even when there is no explicit description thereof.

In addition, it will also be understood that when a first element or layer is referred to as being present “on” a second element or layer, the first element may be disposed directly on the second element or may be disposed indirectly on the second element with a third element or layer being disposed between the first and second elements or layers. It will be understood that when an element or layer is referred to as being “connected to”, or “coupled to” an element or layer, it may be directly on, connected to, or coupled to the other element or layer, or one or more intervening elements or layers may be present. In addition, it will also be understood that when an element or layer is referred to as being “between” two elements or layers, it may be the only element or layer between the two elements or layers, or one or more intervening elements or layers may also be present.

Further, as used herein, when a layer, film, region, plate, or the like may be disposed “on” or “on a top” of another layer, film, region, plate, or the like, the former may directly contact the latter or still another layer, film, region, plate, or the like may be disposed between the former and the latter. As used herein, when a layer, film, region, plate, or the like is directly disposed “on” or “on a top” of another layer, film, region, plate, or the like, the former directly contacts the latter and still another layer, film, region, plate, or the like is not disposed between the former and the latter. Further, as used herein, when a layer, film, region, plate, or the like may be disposed “below” or “under” another layer, film, region, plate, or the like, the former may directly contact the latter or still another layer, film, region, plate, or the like may be disposed between the former and the latter. As used herein, when a layer, film, region, plate, or the like is directly disposed “below” or “under” another layer, film, region, plate, or the like, the former directly contacts the latter and still another layer, film, region, plate, or the like is not disposed between the former and the latter.

In descriptions of temporal relationships, for example, temporal precedent relationships between two events such as “after”, “subsequent to”, “before”, etc., an event may occur therebetween unless “directly after”, “directly subsequent” or “directly before” is not indicated.

It will be understood that, although the terms “first”, “second”, “third”, and so on may be used herein to describe various elements, components, regions, layers and/or sections, these elements, components, regions, layers and/or sections should not be limited by these terms. These terms are used to distinguish one element, component, region, layer or section from an element, component, region, layer or section. Thus, a first element, component, region, layer or section described below could be termed a second element, component, region, layer or section, without departing from the spirit and scope of the present disclosure.

The features of the various embodiments of the present disclosure may be partially or entirely combined with each other, and may be technically associated with each other or operate with each other. The embodiments may be implemented independently of each other and may be implemented together in an association relationship.

In interpreting a numerical value, the value is interpreted as including an error range unless there is no separate explicit description thereof.

It will be understood that when an element or layer is referred to as being “connected to”, or “coupled to” an element or layer, it may be directly on, connected to, or coupled to the other element or layer, or one or more intervening elements or layers may be present. In addition, it will also be understood that when an element or layer is referred to as being “between” two elements or layers, it may be the only element or layer between the two elements or layers, or one or more intervening elements or layers may also be present.

The features of the various embodiments of the present disclosure may be partially or entirely combined with each other, and may be technically associated with each other or operate with each other. The embodiments may be implemented independently of each other and may be implemented together in an association relationship.

Unless otherwise defined, all terms including technical and scientific terms used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

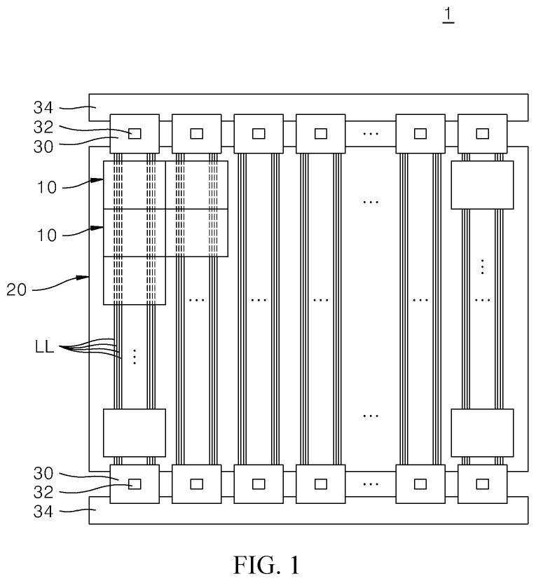

Hereinafter, a display device according to an embodiment of the present disclosure will be described in detail with reference to FIGS. 1 to 13.

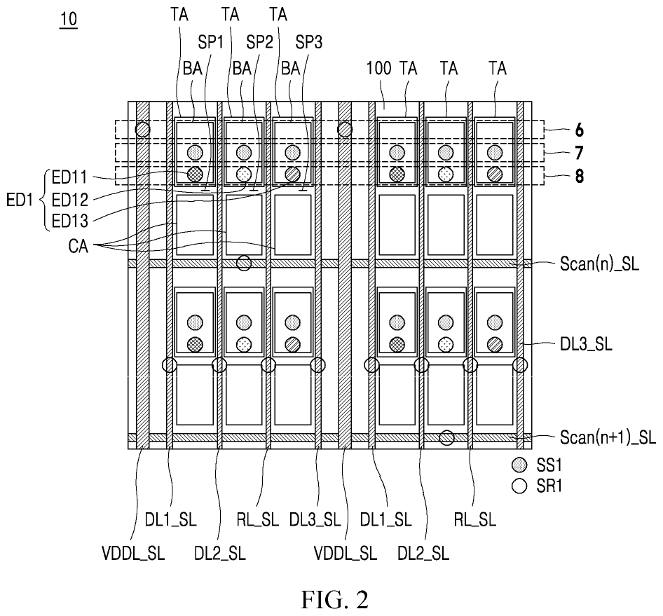

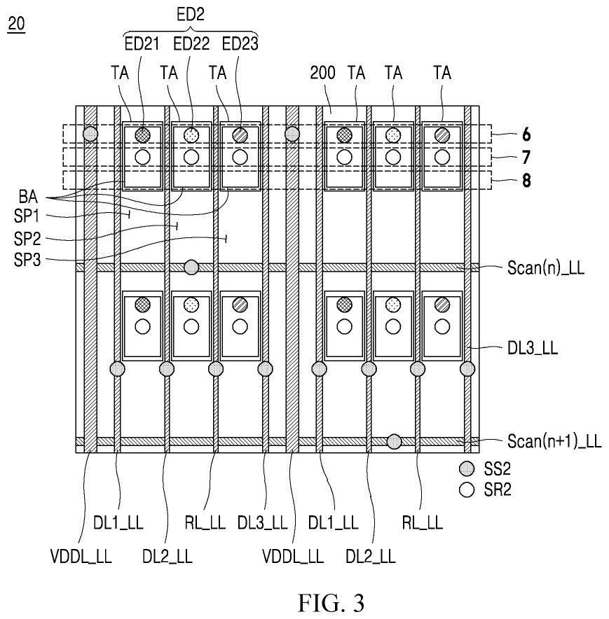

FIG. 1 is a schematic plan view of a display device 1 according to an embodiment of the present disclosure. FIG. 2 is an enlarged plan view of a partial area of a panel unit according to an embodiment of the present disclosure. FIG. 3 is an enlarged plan view of a partial area of a line substrate according to an embodiment of the present disclosure.

Panel units 10, each including a plurality of signal lines SL, may be coupled, in a tiling scheme, to a line substrate 20 including a plurality of link lines LL.

The line substrate 20 may include a second substrate 200 supporting the plurality of link lines LL thereon.

The second substrate 200 may be embodied as an insulating substrate, and may be made of, for example, glass or a transparent plastic material to implement a transparent display device.

One or more circuit films 30 may be disposed at one side or both opposing sides of the second substrate 200 and are electrically connected to the plurality of link lines LL.

The circuit film 30 may be embodied as a flexible circuit film, and a data driver 32 may be disposed on each circuit film 30 in a chip on film (COF) scheme. However, the present disclosure is not limited thereto.

One or more printed circuit boards 34 may be electrically connected to the other side of the circuit film 30 opposite to a side of the circuit film 30 connected to the second substrate 200.

The printed circuit board 34 may be embodied as a flexible printed circuit board (FPCB).

For example, the printed circuit board 34 may include a source printed circuit board and a control printed circuit board.

In this case, the source printed circuit board and the control printed circuit board may be connected to each other using a flat flexible cable (FFC). However, the present disclosure is not limited thereto.

A power management circuit, a timing controller, a level shifter, and the like may be disposed in the printed circuit board 34.

The power management circuit may generate and output various operation voltages required for all circuit components of the display device 1 using an input voltage supplied from an external source.

The timing controller may receive image data and input timing control signals from an external host system, and then supply a plurality of data control signals and the image data to a data driver 32, and supply a plurality of gate control signals to a gate driver.

The data driver 32 may receive the plurality of data control signals and the image data from the timing controller, convert the same into a data signal, and supply a data voltage to a data signal line.

The gate driver may receive the plurality of gate control signals from the timing controller via a level shifter, convert the same into a gate signal (scan signal), and supply a gate voltage (e.g., a scan voltage) to a gate signal line.

For example, the gate driver may be mounted in the panel unit 10 in a gate-in-panel (GIP) scheme. However, the present disclosure is not limited thereto.

Various voltages and signals generated in this way may be transferred to the link lines LL of the line substrate 20 via the circuit film 30.

The plurality of link lines LL may be arranged with each other along one direction and spaced apart from each other.

For example, the plurality of link lines LL may include a plurality of high-potential voltage link lines VDDL_LL, a plurality of low-potential voltage link lines, a plurality of data voltage link lines DL_LL, a plurality of reference voltage link lines RL_LL, a plurality of scan link lines Scan_LL, etc.

The plurality of link lines LL disposed on the line substrate 20 may be electrically connected to the plurality of signal lines SL disposed on the panel unit 10, respectively.

For example, the plurality of signal lines SL may include a plurality of high-potential voltage signal lines VDDL_SL, a plurality of low-potential voltage signal lines, a plurality of data voltage signal lines DL_SL, a plurality of reference voltage signal lines RL_SL, a plurality of scan signal lines Scan_SL, etc.

Various voltages and signals transmitted via the link line LL in this way may be supplied to the pixel via the signal line SL.

The plurality of panel units 10, each including the plurality of signal lines SL, may be provided in a modular form and may be coupled to the line substrate 20 in a tiling scheme in which the plurality of panel units 10 are coupled on the line substrate 20 in a tile form, thereby realizing a tiling display device. For example, each panel unit 10 is coupled to the line substrate in a vertical direction, and the plurality of panel units are positioned with respect to one another in a lateral direction.

For example, the plurality of panel units 10 may be disposed on the line substrate 20 and may be arranged in a matrix form along a plurality of rows and a plurality of columns and may be coupled to the line substrate 20.

In this case, the plurality of panel units 10 may be arranged so that the signal lines SL of the panel unit 10 overlap with the link lines LL of the line substrate 20 in the vertical direction. Thus, a reduction of a transmissive area TA due to the various lines may be reduced. Thus, when the display device 1 according to an embodiment of the present disclosure is implemented as a transparent display device, transmittance may be improved.

Further, in the display device 1 according to an embodiment of the present disclosure, the plurality of panel units 10 may be boned onto the line substrate 20 in the tiling manner. Thus, the display device 1 having a screen of various sizes and shapes may be freely implemented by changing the number and arrangement of the panel units 10 coupled to the line substrate 20.

In some implementations, the number of the panel units 10 may be freely increased. Thus, there is an advantage in that a large screen may be more easily implemented.

Further, in the display device 1 according to an embodiment of the present disclosure, a non-display area may be reduced.

For example, a spacing between the outermost light-emitting element of a panel unit 10 and the outermost light-emitting element of an panel unit 10 adjacent thereto may be identical or substantially identical to a spacing between adjacent light-emitting elements within a same panel unit 10.

Accordingly, the display device 1 according to an embodiment of the present disclosure can reduce the non-display area, and furthermore, a zero-bezel display device 1 in which a bezel area is substantially zero may be realized.

Further, in the display device 1 according to an embodiment of the present disclosure, the plurality of panel units 10 may be disposed on the line substrate 20, and thus the plurality of panel units 10 may be freely attached to and detached from the line substrate 20.

In some implementations, in the display device 1 according to an embodiment of the present disclosure, when a defect occurs in a specific panel unit 10, only the defective panel unit 10 may be removed from the line substrate 20 and may be replaced with a normal panel unit. Thus, an easier and faster repair process may be achieved.

Further, in the display device 1 according to an embodiment of the present disclosure, each of the plurality of link lines LL disposed on the line substrate 20 may function as an auxiliary line for the signal line SL which is disposed in the panel unit 10.

The plurality of link lines LL may be arrange in parallel with each other so as to overlap the plurality of signal lines SL of the panel unit 10 in the vertical direction. Each of the plurality of link lines LL may be electrically connected to each of the plurality of signal lines SL via a connection member 300.

Therefore, the display device 1 according to an embodiment of the present disclosure may lower the electrical resistance of the plurality of signal lines SL. Thus, signal delay such as RC delay and luminance uniformity deterioration due to voltage drop may be reduced. Thus, a low power and high luminance display device may be implemented.

In an example, the panel unit 10 may include a plurality of pixels P.

Each of the plurality of pixels P may include a first sub-pixel SP1, a second sub-pixel SP2, and a third sub-pixel SP3.

The first sub-pixel SP1, the second sub-pixel SP2, and the third sub-pixel SP3 may emit light of different colors.

For example, the first sub-pixel SP1, the second sub-pixel SP2, and the third sub-pixel SP3 may be respectively a red sub-pixel emitting light of a red color (R), a green sub-pixel emitting light of a green color (G), and a blue sub-pixel emitting light of a blue color (B). However, the present disclosure is not limited thereto.

For example, each of the plurality of pixels P may further include a white sub-pixel emitting light of a white color (W).

Each of the plurality of sub-pixels SP1, SP2, and SP3 may include a light-emitting area BA and a circuit area CA.

In addition, each of the plurality of sub-pixels SP1, SP2, and SP3 may further include a transmissive area TA.

Light-emitting elements ED may be disposed in the light-emitting area BA.

The present disclosure describes an example in which the light-emitting element ED is embodied as a micro-LED. However, the present disclosure is not limited thereto.

A plurality of first light-emitting elements ED1 may be disposed in the light-emitting area BA of the panel unit 10.

The plurality of sub-pixels SP1, SP2, and SP3 of the panel unit 10 may include a first light-emitting element ED11 emitting light of a first color, a first light-emitting element ED12 emitting light of a second color, and a first light-emitting element ED13 emitting light of a third color, respectively.

The transmission area TA may be disposed to correspond to the light-emitting area BA, but is not limited thereto and may be additionally disposed in an area other than the light-emitting area BA.

Also, referring to FIGS. 2 to 5, the transmission region TA may be formed to have a larger area than the light-emitting area BA, but is not limited thereto.

The circuit area CA may be an area other than the light-emitting area BA, and may be a circuit area CA in which a driving circuit for driving the plurality of light-emitting elements ED is disposed.

The driving circuit including a thin-film transistor TFT and a storage capacitor Cst may be disposed in the circuit area CA.

In an example, a transmissive area is additionally disposed in each of the plurality of pixels P, such that the display device 1 may be implemented as a transparent display device.

As described above, the plurality of signal lines SL may be disposed on the panel unit 10.

The plurality of signal lines SL may include the data signal line DL_SL, the high-potential voltage signal line VDDL_SL, the reference voltage signal line RL_SL, the low-potential voltage signal line, and the scan signal line Scan_SL.

The data signal line DL_SL, the high-potential voltage signal line VDDL_SL, the reference voltage signal line RL_SL, and the low-potential voltage signal line may extend in a column direction, while the scan signal line Scan_SL may extend in a row direction and may intersect the data signal line DL_SL.

The plurality of data signal lines DL_SL may include a first data signal line DL1_SL, a second data signal line DL2_SL, and a third data signal line DL3_SL which respectively transmit the data signal and supply the data voltage to the sub-pixels SP1, SP2, and SP3.

The plurality of high-potential voltage signal lines VDDL_SL respectively supply a high-potential power voltage to the plurality of sub-pixels SP1, SP2, and SP3. Alternatively or additionally, the plurality of sub-pixels SP1, SP2, and SP3 may share one high-potential voltage signal line VDDL_SL.

The plurality of reference voltage signal lines RL_SL respectively supply a reference power voltage to the plurality of sub-pixels SP1, SP2, and SP3. Alternatively or additionally, the plurality of sub-pixels SP1, SP2, and SP3 may share one reference voltage signal line RL_SL.

The plurality of low-potential voltage signal lines respectively supply a low-potential power voltage to the plurality of sub-pixels SP1, SP2, and SP3. Alternatively or additionally, the plurality of sub-pixels SP1, SP2, and SP3 may share one low-potential voltage signal line.

The scan signal line Scan_SL transmits a scan signal and supplies a scan voltage to each of the plurality of sub-pixels SP1, SP2, and SP3.

The scan signal lines Scan_SL may include a n-th scan signal line Scan(n)_SL and a (n+1)-th scan signal line Scan(n+1)_SL which may be arranged in a sequential manner according to a scan order. In this case, n is a natural number.

The plurality of sub-pixels SP1, SP2, and SP3 may be respectively defined in intersections between the data signal lines DL_SL extending in a first direction and the scan signal lines Scan_SL extending in a second direction intersecting the first direction.

In some implementations, the plurality of sub-pixels SP1, SP2, and SP3 may be arranged in a matrix form. The first light-emitting elements ED1 respectively disposed at positions corresponding to the sub-pixels may be arranged in a matrix form.

In a process of forming the panel unit 10, a defect may occur in the first light-emitting element ED1 and the corresponding defective first light-emitting element ED1 may not properly emit light.

In order to cope this situation, the display device 1 according to an embodiment of the present disclosure has a redundancy structure in which one sub-pixel SP includes a plurality of light-emitting elements emitting light of the same color.

For example, a pair of a first light-emitting element ED1 and a second light-emitting element ED2 emitting light of the same color may constitute one sub-pixel SP.

In this case, the first light-emitting element ED1 may act as a main light-emitting element, and the second light-emitting element ED2 may act as a redundant light-emitting element.

A plurality of second light-emitting elements ED2 may be disposed on the line substrate 20.

The plurality of second light-emitting elements ED2 may be disposed on the line substrate 20 and in an area corresponding to the light-emitting area BA of the panel unit 10.

Therefore, a second light-emitting element ED21 rendering the first color, a second light-emitting element ED22 rendering the second color and a second light-emitting element ED23 rendering the third color may be disposed on the line substrate 20 and respectively in positions corresponding to positions of the plurality of sub-pixels SP1, SP2, and SP3 of the panel unit 10.

It should be noted that in a sub-pixel that does not includes a first light-emitting element, e.g., ED12 in a second sub-pixel SP2, there is only one first light-emitting element, and there is no second light-emitting element.

Unlike the panel unit 10, a separate circuit area CA other than the light-emitting area BA may not be disposed on the line substrate 20.

The plurality of second light-emitting elements ED2 may be electrically connected to the driving circuit disposed in the circuit area CA of the panel unit 10, and may respectively receive the driving signals to drive the second light-emitting elements ED2 therefrom.

For example, the thin-film transistor TFT for applying the driving signal to the first light-emitting element ED1 may be disposed in the panel unit 10. The thin-film transistor TFT may also apply the driving signal to the second light-emitting element ED2 that renders the same color as the color which the first light-emitting element ED1 renders.

As described above, the plurality of link lines LL may be disposed on the line substrate 20, and a signal provided via the circuit film 30 may be applied to the signal line SL via the link line LL.

The plurality of link lines LL may include the data link line DL_LL, the high-potential voltage link line VDDL_LL, the reference voltage link line RL_LL, the low-potential voltage link line, and the scan link line Scan_LL, etc.

The data link line DL_LL, the high-potential voltage link line VDDL_LL, the reference voltage link line RL_LL, and the low-potential voltage link line may extend in the column direction, while the scan link line Scan_LL may extend in the row direction and intersect the data link line DL_LL.

The plurality of data link lines DL_LL may include a first data link line DL1_LL, a second data link line DL2_LL, and a third data link line DL3_LL which are respectively electrically connected to the first data signal line DL1_SL, the second data signal line DL2_SL, and the third data signal line DL3_SL.

The plurality of high-potential voltage link lines VDDL_LL may be respectively electrically connected to the plurality of high-potential voltage signal lines VDDL_SL. The plurality of reference voltage link lines RL_LL may be respectively electrically connected to the plurality of reference voltage signal lines RL_SL. The plurality of low-potential voltage link lines may be respectively electrically connected to the plurality of low-potential voltage signal lines.

The plurality of scan link lines Scan_LL may include an n-th scan link line Scan(n)_LL and an (n+1)-th scan link line Scan(n+1)_LL which may be respectively electrically connected to the n-th scan signal line Scan(n)_SL and the (n+1)-th scan signal line Scan(n+1)_SL. In this case, n is a natural number.

A second signal transmitting connection portion SS2 may be formed at each of the plurality of link lines LL formed as described above. A first signal receiving connection portion SR1 may be formed at each of the plurality of signal lines SL.

For example, at least one second signal transmitting connection portion may be formed on each of the data link line DL_LL, the high-potential voltage link line VDDL_LL, the reference voltage link line RL_LL, and the scan link line Scan_LL SS2.

In this case, the second signal transmitting connection portion SS2 may mean a partial area of the link line LL. However, the present disclosure is not limited thereto, and the second signal transmitting connection portion SS2 may be embodied in a form of a separate connection electrode electrically connected to a corresponding link line LL.

For example, at least one first signal receiving connection portion SR1 may be formed on each of the data signal line DL_SL, the high-potential voltage signal line VDDL_SL, the reference voltage signal line RL_SL, and the scan signal line Scan_SL.

In this case, the first signal receiving connection portion SR1 may mean a partial area of the signal line SL. However, the present disclosure is not limited thereto, and the first signal receiving connection portion SR1 may be embodied in a form of a separate connection electrode electrically connected to a corresponding signal line SL.

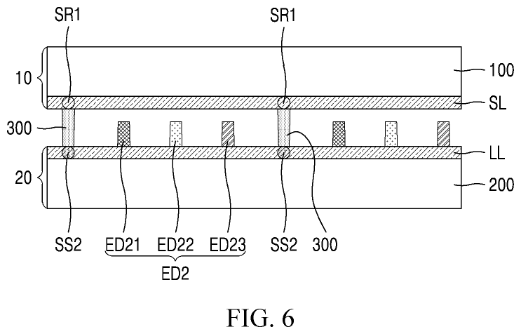

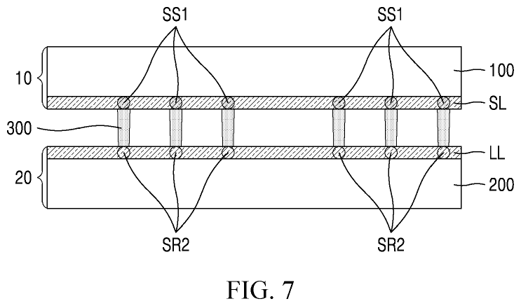

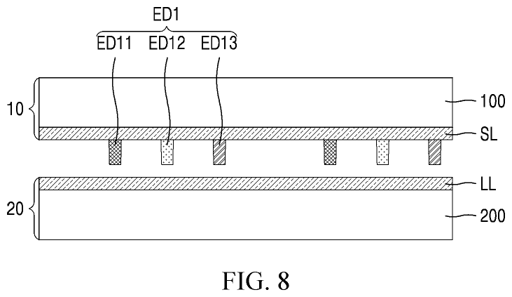

Referring to FIGS. 6 to 8, the connection member 300 may be disposed between the second signal transmitting connection portion SS2 of the link line LL and the first signal receiving connection portion SR1 of the signal line SL, such that the second signal transmitting connection portion SS2 and the first signal receiving connection portion SR1 may be electrically connected to each other via the connection member 300.

Accordingly, a signal transmitted via the link line LL may be transmitted to the signal line SL via the second signal transmitting connection portion SS2 and the first signal receiving connection portion SR1.

The connection member 300 may be made of a conductive material.

For example, the connection member 300 may be made of a conductive paste such as a metal adhesive, metal powers, a metal layer, conductive ink, or silver paste. However, the present disclosure is not limited thereto.

In the light-emitting area BA where the first light-emitting element ED1 and the second light-emitting element ED2 are disposed, the line substrate 20 and the panel unit 10 may be electrically connected to each other via the connection member 300.

For example, a first signal transmitting connection portion SS1 may be formed at the signal line SL electrically connected to the first light-emitting element ED1. A second signal receiving connection portion SR2 may be formed at the link line LL electrically connected to the second light-emitting element ED2.

The signal line SL electrically connected to the first light-emitting element ED1 may be embodied in a form of a separate connection electrode that may be electrically connected to the circuit area CA of the panel unit 10 and may deliver a driving signal that drives the first light-emitting element ED1 thereto.

Further, the link line LL electrically connected to the second light-emitting element ED2 may be embodied in a form of a separate connection electrode that may be electrically connected to the signal line SL electrically connected to the first light-emitting element ED1 and may receive a driving signal for driving the second light-emitting element ED2 from the circuit area CA of the panel unit 10.

The connection member 300 may be disposed between the first signal transmitting connection portion SS1 of the signal line SL and the second signal receiving connection portion SR2 of the link line LL so as to electrically connect the first signal transmitting connection portion SS1 and the second signal receiving connection portion SR2 to each other.

In some implementations, the driving signal for the first light-emitting element ED1 and the second light-emitting element ED2 transmitted via the signal line SL may be transferred to the link line LL electrically connected to the second light-emitting element ED2 via the first signal transmitting connection portion SS1 and the second signal receiving connection portion SR2.

As described above, the display device 1 according to an embodiment of the present disclosure may have a redundancy structure in which the redundant light-emitting element is disposed on the line substrate 20 separate from the panel unit 10 on which the main light-emitting element is disposed.

Accordingly, even when a defect occurs in the main light-emitting element, the redundant light-emitting element may emit light in place of the main light-emitting element, thereby removing the occurrence of the defective pixel due to the defective main light-emitting element.

If the defective light-emitting element is directly repaired through a defective pixel repair process without adopting the redundancy structure, the element such as the thin-film transistor or various layers may be damaged in the defective pixel repair process.

Therefore, in the display device 1 according to an embodiment of the present disclosure, the thin-film transistor in the panel unit 10 may not be affected by the defective pixel repair process, such that the occurrence of the defective pixel may be reduced while reducing the damage to the thin-film transistor.

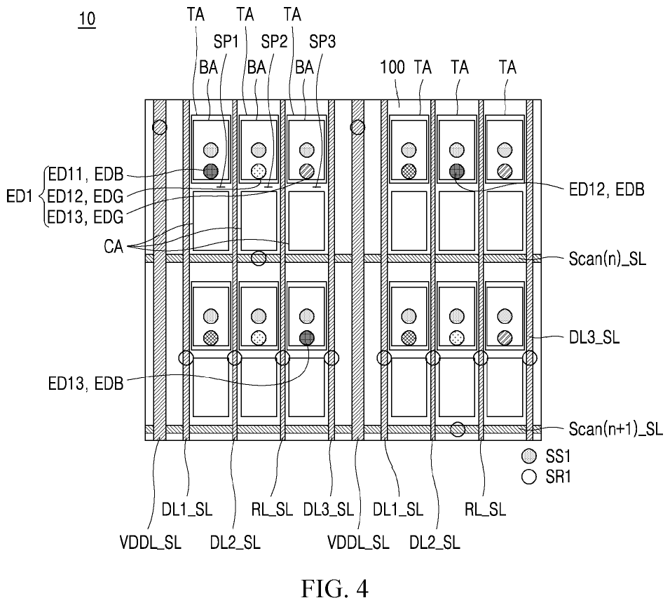

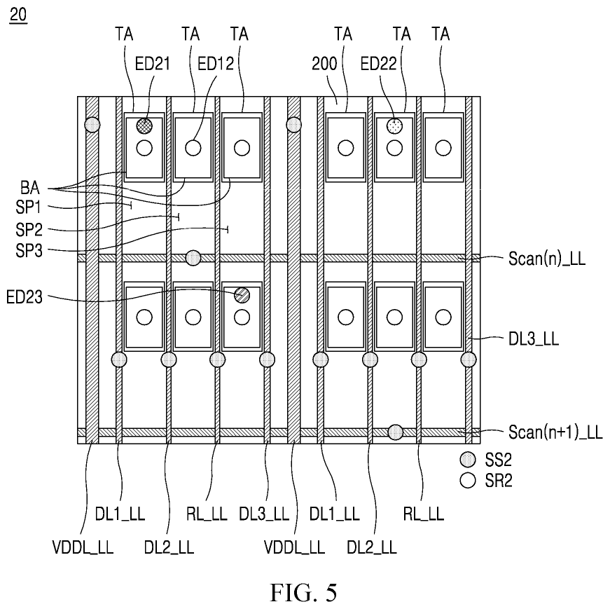

Referring to FIG. 4 and FIG. 5, in the display device 1 according to an embodiment of the present disclosure, the second light-emitting element ED2 may be selectively positioned.

In some implementations, each of the first light-emitting elements ED1 may be positioned in a corresponding manner to each of the sub-pixels SP1, SP2, and SP3. Each of the second light-emitting elements ED2 may not be disposed in a corresponding manner to each of the sub-pixels SP1, SP2, and SP3 but may be selectively disposed in each of the sub-pixels SP1, SP2, and SP3.

For example, the first light-emitting element ED1 may include a normal light-emitting element EDG that can emit light and a defective light-emitting element EDB that cannot emit light.

Referring to FIG. 4, in one pixel, the first light-emitting element ED11 emitting light of the first color may be the normal light-emitting element EDG, while each of the first light-emitting element ED12 emitting light of the second color and the first light-emitting element ED13 emitting light of the third color may be the defective light-emitting element EDB.

Further, in an pixel, the first light-emitting element ED12 emitting light of the second color may be the defective light-emitting element EDB. In still an pixel, the first light-emitting element ED13 emitting light of the third color may be the defective light-emitting element EDB. In still yet an pixel, all the first light-emitting elements ED1 may be the normal light-emitting elements EDG.

In this case, each of the sub-pixels SP1, SP2, and SP3 including the defective light-emitting element EDB may include the second light-emitting element ED2, while each of the sub-pixels SP1, SP2, and SP3 including the normal light-emitting element EDG may not include the second light-emitting element ED2.

Referring to FIG. 5, the second light-emitting element ED2 may be disposed only in each of the sub-pixels SP1, SP2 and SP3 in which the defective light-emitting element EDB is present in FIG. 4.

That is, the second light-emitting element ED2 may be disposed in each of the sub-pixels SP1, SP2, and SP3 where the defective first light-emitting element ED1 which cannot emit light is disposed. The second light-emitting element ED2 may not be disposed in each of the sub-pixels SP1, SP2, and SP3 where the normal first light-emitting element ED1 which can emit light is disposed.

In the display device 1 according to an embodiment of the present disclosure, the first light-emitting element ED1 as the main light-emitting element may be formed in the panel unit 10, and then, whether the first light-emitting element ED1 is defective may be checked before the second light-emitting element ED2 as the redundant light-emitting element is formed.

After examining whether the first light-emitting element ED1 is defective, the second light-emitting element ED2 may be additionally disposed on the line substrate 20 only in the sub-pixel corresponding to the first light-emitting element ED1 as determined to be defective. As such, after the panel unit 10 that has a defective first light-emitting element ED1 is coupled to the line substrate 20, a second light-emitting element ED2 is present in the corresponding subpixel that includes the defective first light-emitting element ED1. For a subpixel that includes all normal first light-emitting element ED1 of a panel unit 10, e.g., all first light-emitting elements ED1 are in functioning condition, the light substrate 20 will not include a second light-emitting element for the corresponding subpixel.

As such, for a subpixel that includes a defective first light-emitting element ED1, there is a second light-emitting element ED2 in the same sub-pixel and configured to emit light of the same color as the defective first light-emitting element ED1. The second light-emitting element ED2 is in a functioning condition. For a subpixel that includes a first light-emitting element ED1 in a functioning condition, there is no second light-emitting element ED2 configured to emit light of the same color as the first light-emitting element ED1 in the functioning condition.

In some implementations, in the display device 1 according to an embodiment of the present disclosure, the redundant light-emitting element may be disposed only in the sub-pixel where the defective main light-emitting element is disposed, while the redundant light-emitting element may not be disposed in the sub-pixel in which the normal main light-emitting element is disposed. Thus, an unnecessary redundant light-emitting element does not need to be disposed, such that a great cost reduction effect may be obtained.

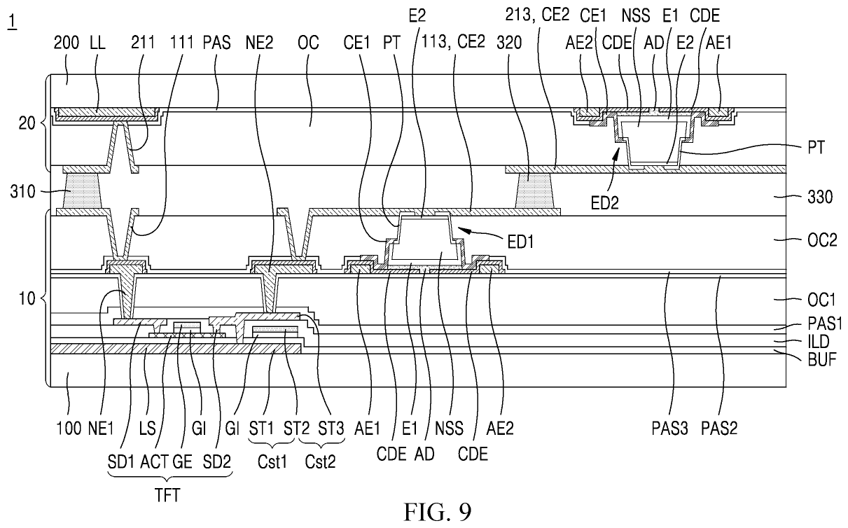

Hereinafter, with reference to FIGS. 9 to 13, various connection structures between the line substrate 20 and the panel unit 10 will be described based on a cross-sectional view of one sub-pixel in a state in which the line substrate 20 and the panel unit 10 are coupled to each other.

Referring to FIG. 9, the line substrate 20 and the panel unit 10 may be coupled to each other via an optical resin layer 330 disposed between the line substrate 20 and the panel unit 10, and may be electrically connected to each other via a plurality of connection members 310 and 320.

For example, the optical resin layer 330 may include an optical clear resin (OCR).

Hereinafter, the panel unit 10 is described first, and then the line substrate 20 is described.

The panel unit 10 may include a first substrate 100, a thin-film transistor TFT disposed on the first substrate 100, a storage capacitor Cst, and various lines.

The first substrate 100 may be made of a transparent material including glass or plastic.

A light-blocking layer LS may be disposed on the first substrate 100 so as to prevent light incident from a position under the first substrate 100 from invading an active layer ACT of the thin-film transistor TFT, such that leakage current may be reduced.

A buffer layer BUF may be disposed on the light-blocking layer LS so as to block impurities or moisture passing through the first substrate 100.

The thin-film transistor TFT may be disposed on the buffer layer BUF.

The thin-film transistor TFT may act as a driving thin-film transistor that provides a driving signal for driving the light-emitting element ED.

The thin-film transistor TFT may include the active layer ACT, a first source/drain electrode SD1, a second source/drain electrode SD2, and a gate electrode GE.

A gate insulating layer GI may be disposed between the active layer ACT and the gate electrode GE.

An interlayer insulating layer ILD may be disposed on the active layer ACT and the gate electrode GE. The interlayer insulating layer ILD may have a pair of contact-holes defined therein respectively exposing source and drain areas of the active layer ACT.

The first source/drain electrode SD1 and the second source/drain electrode SD2 may be disposed on the interlayer insulating layer ILD, and may be electrically connected to the active layer ACT via the pair of contact-holes, respectively.

The first source/drain electrode SD1 may act as a source electrode, and the second source/drain electrode SD2 may act as a drain electrode.

The first data signal line DL1_SL, the second data signal line DL2_SL, and the third data signal line DL3_SL as the signal lines SL formed in the panel unit 10, and the first source/drain electrode SD1 and the second source/drain electrode SD2 may be made of the same material and may be disposed in the same layer. The first data signal line DL1_SL, the second data signal line DL2_SL, and the third data signal line DL3_SL as the signal lines SL formed in the panel unit 10 may be electrically connected to the first source/drain electrode SD1 and the second source/drain electrode SD2.

The storage capacitor Cst may be spaced apart from the thin-film transistor TFT, and may include a first storage capacitor Cst1 and a second storage capacitor Cst2.

The storage capacitor Cst may store a voltage therein so that the light-emitting element ED continuously maintains the same state for one frame.

The first storage capacitor Cst1 may include a first capacitor electrode ST1 and a second capacitor electrode ST2, while the second storage capacitor Cst2 may include the second capacitor electrode ST2 and a third capacitor electrode ST3.

The first capacitor electrode ST1 may be integrally formed with the light-blocking layer LS.

The second capacitor electrode ST2 may be disposed on the first capacitor electrode ST1, and the second capacitor electrode ST2 may be made of the same material as a material of the gate electrode GE.

The buffer layer BUF and the gate insulating layer GI may be disposed between the first capacitor electrode ST1 and the second capacitor electrode ST2 and thus may act as a dielectric layer constituting the first storage capacitor Cst1.

The third capacitor electrode ST3 may be integrally formed with the second source/drain electrode SD2.

The second source/drain electrode SD2 may be electrically connected to the light-blocking layer LS via a contact-hole extending through the buffer layer BUF and the interlayer insulating layer ILD.

The interlayer insulating layer ILD may be disposed between the second capacitor electrode ST2 and the third capacitor electrode ST3 and may act as a dielectric layer constituting the second storage capacitor Cst2.

A first passivation layer PAS1 may be formed to cover the thin-film transistor TFT.

The first passivation layer PAS1 may serve to prevent penetration of impurities or moisture into the thin-film transistor TFT.

A first overcoat layer OC1 may be formed on the first passivation layer PAS1.

The first overcoat layer OC1 may act as a first planarization layer, and may serve to reduce a step caused by a lower line such as the thin-film transistor TFT so as to planarize a top surface.

The first overcoat layer OC1 may include a photoactive compound (PAC). However, the present disclosure is not limited thereto.

A pair of via-holes or a pair of contact-holes respectively exposing portions of surfaces of the first source/drain electrode SD1 and the second source/drain electrode SD2 may extend through the first overcoat layer OC1 and the first passivation layer PAS1.

A second passivation layer PAS2 including an insulating material may be disposed on the first overcoat layer OC1. The second passivation layer PAS2 may extend along and on an inner side surface of each of the pair of via-holes extending through the first overcoat layer OC1 and the first passivation layer PAS1.

However, the second passivation layer PAS2 may be formed in a pattern so as to expose portions of the surfaces of the first source/drain electrode SD1 and the second source/drain electrode SD2.

A first source/drain connection electrode NE1 and a second source/drain connection electrode NE2 may be disposed on the second passivation layer PAS2. The first source/drain connection electrode NE1 may be electrically connected to the first source/drain electrode SD1 via one of the pair of via-holes, while the second source/drain connection electrode NE2 may be electrically connected to the second source/drain electrode SD2 via the other of the pair of via-holes.

The first light-emitting element ED1 may be disposed on the second passivation layer PAS2.

The present disclosure describes an example in which the first light-emitting element ED1 is directly coupled to the panel unit 10 in a self-assembly scheme. However, the present disclosure is not limited thereto.

In this case, the panel unit 10 may function as a self-assembly substrate capable of fixing the first light-emitting element ED1 thereto in a self-assembly scheme. The panel unit 10 may 10 may have a self-assembly structure.

A first assembly electrode AE1, a second assembly electrode AE2, a clad electrode CDE, a first line electrode CE1, and an adhesive layer AD may be formed on the second passivation layer PAS2.

The first assembly electrode AE1 and the second assembly electrode AE2 may be spaced apart from each other and may correspond to each of a plurality of first light-emitting element ED1 assembled in a self-assembly process.

Each of the assembly electrodes AE1 and AE2 may include a transparent electrode material including indium-tin-oxide (ITO).

The first assembly electrode AE1 and the second assembly electrode AE2 may generate an electric field therebetween when voltage is applied thereto in the self-assembly process. Thus, the first light-emitting element ED1 which has moved into an assembly space defined between the first assembly electrode AE1 and the second assembly electrode AE2 may be stably fixed therein.

The clad electrode layer CDE may be formed on the first assembly electrode AE1 and the second assembly electrode AE2. The clad electrode layer CDE may cover the first assembly electrode AE1 and the second assembly electrode AE2.

The first assembly electrode AE1 and the second assembly electrode AE2, and the first source/drain connection electrode NE1 and the second source/drain connection electrode NE2 may be made of the same material and may be disposed in the same layer.

The clad electrode layer CDE may be also formed on the first source/drain connection electrode NE1 and the second source/drain connection electrode NE2. The clad electrode layer CDE may be disposed to cover the first source/drain connection electrode NE1 and the second source/drain connection electrode NE2.

The clad electrode layer CDE may prevent corrosion of the first assembly electrode AE1 and the second assembly electrode AE2 in the self-assembly process carried out in fluid, such that the electric field for the assembly of the first light-emitting element ED1 may be generated easily.

The clad electrode layer CDE may include copper (Cu).

A spacing between a pair of clad electrode layers CDE respectively formed on the first assembly electrode AE1 and the second assembly electrode AE2 may be smaller than a spacing between the first assembly electrode AE1 and the second assembly electrode AE2.

In some implementations, an assembly position of the first light-emitting element ED1 disposed in the assembly space formed between the first assembly electrode AE1 and the second assembly electrode AE2 may be more accurately fixed.

A third passivation layer PAS3 may be disposed on the clad electrode layer CDE.

A portion of the third passivation layer PAS3 may cover a partial area of a top face of the clad electrode layer CDE while a remaining portion of the third passivation layer PAS3 may cover an entire surface of the first substrate 100.

The third passivation layer PAS3 may be formed not to cover an area corresponding to the assembly space formed between the first assembly electrode AE1 and the second assembly electrode AE2 so as to be exposed.

The assembly space formed in this way may designate a position to which the first light-emitting element ED1 is fixed.

The adhesive layer AD may be disposed on a portion of the clad electrode layer CDE corresponding to the assembly space, and the adhesive layer AD may serve to adhesively fix the first light-emitting element ED1 to the clad electrode layer.

The adhesive layer AD may be made of a thermally-curable material or an optically-curable material. However, the present disclosure is not limited thereto.

The first light-emitting element ED1 may be disposed on the adhesive layer AD.

The present disclosure describes an example in which the first light-emitting element ED1 is embodied as a vertical micro-LED. However, the present disclosure is not limited thereto, and the first light-emitting element ED1 may be embodied as a horizontal micro-LED.

Alternatively or additionally, the first light-emitting element ED1 may be embodied as a micro-LED having a flip chip shape or a micro-LED having a nanorod shape.

The first light-emitting element ED1 may include a semiconductor structure NSS, a first electrode E1, and a second electrode E2.

The first electrode E1 of the first light-emitting element ED1 may act as a first cathode electrode, and the second electrode E2 thereof may act as a first anode electrode.

The semiconductor structure NSS may be embodied as a nitride semiconductor structure, and may include a first semiconductor layer, an active layer disposed on one side of the first semiconductor layer, and a second semiconductor layer.

In some implementations, the semiconductor structure NSS includes a staggered shape in a cross-sectional view, and the protective layer pattern PT may at least partially follow the staggered shape of the semiconductor structure NSS.

The first electrode E1 may be disposed on one surface of the first semiconductor layer where the active layer is not disposed, while the second electrode E2 may be disposed on one surface of the second semiconductor layer where the active layer is not disposed.

For example, the first electrode E1 may be formed to extend along and on one surface of the first semiconductor layer and along and on a portion of a side surface of the first semiconductor layer.

The first semiconductor layer may be configured for supplying electrons to the active layer, and may include a nitride semiconductor containing first conductivity type impurities.

For example, the first conductivity-type impurity may include an N-type impurity.

The active layer may include a Multi-Quantum-Well (MQW) structure. The second semiconductor layer may be configured for injecting holes into the active layer, and may include a nitride semiconductor containing second conductivity type impurities.

For example, the second conductivity type impurity may include a P type impurity.

A protective layer pattern PT may be formed to cover at least a portion of an outer surface of the first light-emitting element ED1.

The protective layer pattern PT may serve to prevent damage that may occur to a side surface of the semiconductor structure NSS in a dry etching process to form the semiconductor structure NSS, thereby supplementing the characteristics of the element.

The other surface of the first semiconductor layer opposite to one surface of the first semiconductor layer on which the active layer is disposed may contact the adhesive layer AD such that the first light-emitting element ED may be fixed to the adhesive layer AD.

The protective layer pattern PT may be separated from the adhesive layer AD by the first electrode E1 and/or the semiconductor structure NSS.

A first line electrode CE1 disposed to surround the first electrode E1 may be formed on a side surface of the first light-emitting element ED1 and may contact and be electrically connected to the first electrode E1.

One side of the first line electrode CE1 may cover the clad electrode layer CDE, and may contact and be electrically connected to the clad electrode layer CDE.

Further, a second line electrode CE2 may be formed on the first light-emitting element ED1, and may contact and be electrically connected to the second electrode E1. In some implementations, the second line electrode CE2 is at least partially on a same level as the first line electrode CE1. For example, the first line electrode CE1 and the second line electrode CE2 are both on the third passivation layer PAS3 and on a layer of a metal material of the clad electrode layer CDE.

A second overcoat layer OC2 may be formed to cover the first light-emitting element ED1.

The second overcoat layer OC2 may act as a second planarization layer, and may serve to reduce a step caused by a lower line such as the first light-emitting element ED1 to planarize a top surface.

The second overcoat layer OC2 may include a photoactive compound (PAC). However, the present disclosure is not limited thereto.

A first line connection electrode 111 and the second line electrode CE2 may be formed on the second overcoat layer OC2.

The first line connection electrode 111 and the second line electrode CE2 may be made of the same material and may be disposed in the same layer.

Each of a pair of contact-holes may extend through the second overcoat layer OC2 and the third passivation layer PAS3 so as to expose a portion of a surface of the clad electrode layer CDE disposed on each of the first source/drain connection electrode NE1 and the second source/drain connection electrode NE2.

Further, the second overcoat layer OC2 may be formed not to cover at least a portion of a surface of the second electrode E2 of the first light-emitting element ED1 so as to be exposed.

In some implementations, the first line connection electrode 111 may be electrically connected to the first source/drain connection electrode NE1 via a portion of the clad electrode layer CDE exposed to an outside through one of the contact-holes. The second line electrode CE2 may be electrically connected to the second source/drain connection electrode NE2 via a portion of the clad electrode layer CDE exposed to the outside through the other of the contact-holes.

In this case, the second line electrode CE2 having one side electrically connected to the second source/drain connection electrode NE2 may cover a top face of the first light-emitting element ED1 so as to be electrically connected to the second electrode E2 thereof.

The second line electrode CE2 may be referred to as a first anode connection electrode 113 electrically connected to the second electrode E2 as the first anode electrode.

In this way, the first anode connection electrode 113 may be electrically connected to the second source/drain electrode SD2 of the thin-film transistor TFT, and the second electrode E2 as the first anode electrode of the first light-emitting element ED1, such that the driving signal from the thin-film transistor TFT may be applied to the first anode electrode of the first light-emitting element ED1.

In some implementations, the first anode connection electrode 113 overlaps with the protective layer pattern PT.

In an example, the line substrate 20 may include the second substrate 200, the second light-emitting element ED2 disposed on the second substrate 200, and the various link lines LL.

The second substrate 200 may be made of a transparent material including glass or plastic.

The present disclosure describes an example in which the second light-emitting element ED2 is directly coupled to the line substrate 20 in a self-assembly scheme like the first light-emitting element ED1 as described above. However, the present disclosure is not limited thereto.

In this case, the line substrate 20 may function as a self-assembly substrate capable of fixing the second light-emitting element ED2 thereto in a self-assembly scheme. The line substrate 20 may have a self-assembly structure.

A structure of the second light-emitting element ED2 and the self-assembly structure for fixing the second light-emitting element ED2 thereto in a self-assembly scheme may be identical with the structure of the first light-emitting element ED1 and the self-assembly structure for fixing the first light-emitting element ED1 thereto in the self-assembly scheme, as described above. Thus, detailed description thereof will be omitted.

Therefore, the first assembly electrode AE1, the second assembly electrode AE2, the clad electrode CDE, the first line electrode CE1, and the adhesive layer AD may be disposed on the second substrate 200 to constitute the self-assembly structure.

In some implementations, the second light-emitting element ED2 including the first electrode E1, the semiconductor structure NSS, and the second electrode E2 may be fixed by the self-assembly structure formed on the second substrate 200.

In this case, the first electrode E1 of the second light-emitting element ED2 may act as a second cathode electrode, and the second electrode E2 thereof may act as a second anode electrode.

The link line LL may be formed on the second substrate 200.

The link line LL and the first assembly electrode AE1 and the second assembly electrode AE2 may be made of the same material and may be disposed in the same layer.

Further, the clad electrode layer CDE may be formed on the link line LL so as to cover the link line LL.

A passivation layer PAS may be formed on the self-assembly structure formed in this way and the link line LL. An overcoat layer OC may be formed to cover the passivation layer PAS and the second light-emitting element ED2.

A second line connection electrode 211 and the second line electrode CE2 may be formed on the overcoat layer OC.

The second line connection electrode 211 and the second line electrode CE2 may be made of the same material and may be disposed in the same layer.

A contact-hole extending through the overcoat layer OC and the passivation layer PAS may be formed so that a portion of a surface of the clad electrode layer CDE disposed on the link line LL is exposed.

Further, the overcoat layer OC may be formed not to cover at least a portion of a surface of the second electrode E2 of the second light-emitting element ED2 so as to be exposed.

In some implementations, the second line connection electrode 211 may be electrically connected to the link line LL via a portion of the clad electrode layer CDE exposed to the outside through the contact-hole. The second line electrode CE2 may be electrically connected to the second electrode E2 of the second light-emitting element ED2 exposed to the outside.

Therefore, the second line electrode CE2 of the second light-emitting element ED2 may be referred to as a second anode connection electrode 213 electrically connected to the second electrode E2 as the second anode electrode of the second light-emitting element ED2.

The line substrate 20 thus formed may be coupled to the panel unit 10 via the optical resin layer 330 which may be interposed therebetween. The line substrate 20 and the panel unit 10 may be electrically connected to each other via the plurality of connection members 300.

The first connection member 310 may be disposed between the first line connection electrode 111 and the second line connection electrode 211 such that the first line connection electrode 111 and the second line connection electrode 211 may be electrically connected to each other via the first connection member 310.

In some implementations, the signal provided through the link line LL of the line substrate 20 may be applied to the first source/drain connection electrode NE1 and the first source/drain electrode SD1 of the thin-film transistor TFT via the second line connection electrode 211 and the first line connection electrode 111.

In this case, the link line LL of the line substrate 20 may be the first data link line DL1_LL.

Further, the second connection member 320 may be disposed between the first anode connection electrode 113 and the second anode connection electrode 213, such that the first anode connection electrode 113 and the second anode connection electrode 213 may be electrically connected to each other via the second connection member 320. As such, the second electrode E2 of the first light-emitting element ED1 and the second electrode E2 of the second light-emitting element ED2 are connected together through the connection electrodes 113, 213 and the second connection member 320.

It should be appreciated that in some illustrative examples, the second electrodes E2 are configured as anode electrode. In some other examples, the second electrodes E2 may be configured as cathode electrodes of the first light-emitting element ED1 and/or the second light-emitting element ED2.

The driving signal from the thin-film transistor TFT may be applied to the second anode electrode of the second light-emitting element ED2 via the first anode connection electrode 113 of the first light-emitting element ED1 and the second anode connection electrode 213 of the second light-emitting element ED2.

The first light-emitting element ED1 and the second light-emitting element ED2 electrically connected to each other via the second connection member 320 may emit light of the same color.

In some implementations, the first anode electrode of the first light-emitting element ED1 and the second anode electrode of the second light-emitting element ED2 in a first sub-pixel SP1 may share the driving signal provided from the thin-film transistor TFT disposed in the panel unit 10.

In some implementations, in a second sub-pixel SP2 that is configured to emit light another color different from that of the first sub-pixel SP1, two light-emitting elements configured to emit light of the same another color are connected to driving signals provided from two different thin-film transistor TFT disposed in the respective panel unit. The second sub-pixel SP2 may be adjacent to the first sub-pixel SP1 in a row direction or in a column direction.

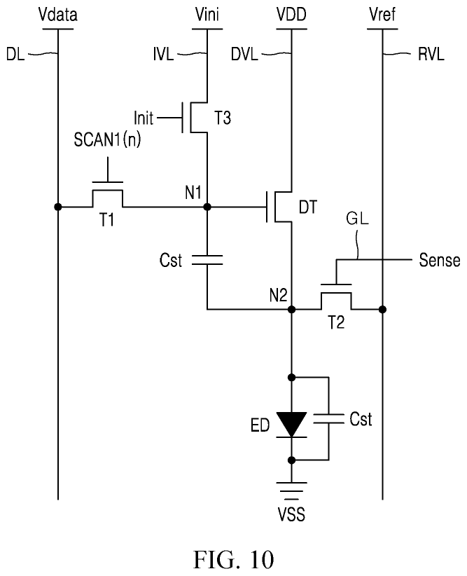

FIG. 10 is a circuit diagram of a case where the anode electrode of the light-emitting element ED of the line substrate 20 and the anode electrode of the light-emitting element ED of the panel unit 10 are electrically connected to each other and thus act as a common electrode according to an embodiment of the present disclosure.

FIG. 10 shows a 4T2C structure in which three thin-film transistors T1, T2, and T3 in addition to the driving thin-film transistor DT are disposed in a sub-pixel SP, and two storage capacitors Cst are disposed in the sub-pixel by way of example. However, the present disclosure is not limited thereto.

The driving thin-film transistor DT may be electrically connected to and disposed between the light-emitting element ED and a high-potential driving voltage VDD.

The high-potential driving voltage VDD may be supplied via a driving voltage line DVL.

One electrode of the light-emitting element ED, for example, an anode electrode thereof may be electrically connected to the driving thin-film transistor DT, while the other electrode of the light-emitting element ED, for example, a cathode electrode thereof may be electrically connected to a low-potential driving voltage VSS.

The first thin-film transistor T1 may be electrically connected to and disposed between a data line DL and a first node N1. The first node N1 may be a gate node of the driving thin-film transistor DT.

The first thin-film transistor T1 may be controlled based on an n-th scan signal Scan1(n) supplied via a gate line GL.

The first thin-film transistor T1 may control the application of a data voltage Vdata supplied via the data line DL to the first node N1 as the gate node of the driving thin-film transistor DT.

The second thin-film transistor T2 may be electrically connected to and disposed between a reference voltage line RVL and a second node N2.

The second node N2 may be a source node or a drain node of the driving thin-film transistor DT.

The second thin-film transistor T2 may be controlled based on a sense signal Sense supplied via the gate line GL.

The second thin-film transistor T2 may control application of a reference voltage Vref supplied via the reference voltage line RVL to the second node N2.

The third thin-film transistor T3 may be electrically connected to and disposed between an initialization voltage line IVL and the first node N1.

The third transistor T3 may be controlled based on an initialization signal Init supplied via the gate line GL.

The third transistor T3 may control application of an initialization voltage Vini to the first node N1 as the gate node of the driving thin-film transistor DT.

The storage capacitor Cst may be electrically connected to and disposed between the first node N1 and the second node N2. The storage capacitor Cst may maintain the data voltage Vdata for one frame period.

An storage capacitor Cst may be electrically connected to and disposed between a node to which the anode electrode of the light-emitting element ED is connected and a node to which the low-potential driving voltage VSS is connected, and may store voltage therein.

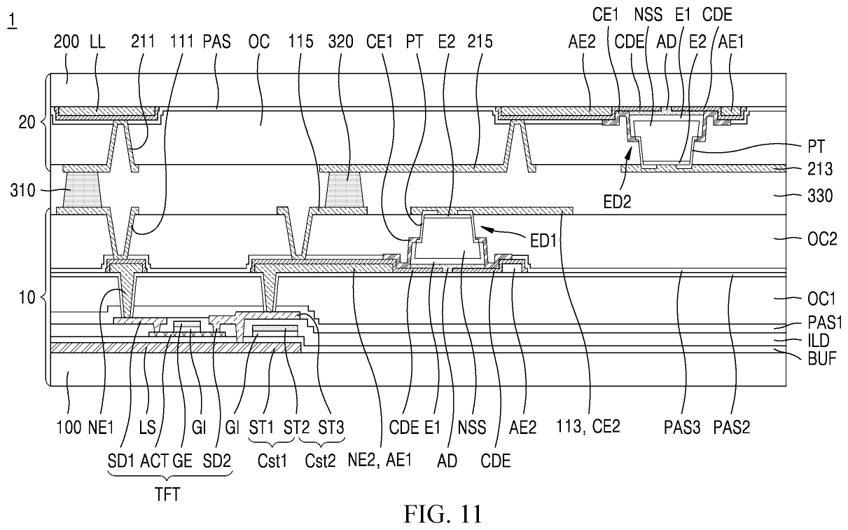

FIG. 11 is a detailed cross-sectional view of one sub-pixel SP in a state in which the line substrate 20 and the panel unit 10 are coupled to each other according to an embodiment of the present disclosure.

Descriptions about the display device 1 according to an embodiment of the present disclosure as described with reference to FIG. 11 duplicate with the description about the display device 1 as described with reference to FIG. 9 will be omitted. Following description will be based on differences therebetween.

The thin-film transistor TFT may be formed on the first substrate 100.

The first passivation layer PAS1 and the first overcoat layer OC1 may be stacked on the thin-film transistor TFT.

Each of a pair of via-holes or a pair of contact-holes extending thorough the first overcoat layer OC1 and the first passivation layer PAS1 may be formed so as to expose a portion of the surface of each of the first source/drain electrode SD1 and the second source/drain electrode SD2 of the thin-film transistor TFT.

The second passivation layer PAS2 including an insulating material may be disposed on the first overcoat layer OC1. The second passivation layer PAS2 may extend along and on an inner side surface of each of the pair of via-holes extending through the first overcoat layer OC1 and the first passivation layer PAS1.

However, the second passivation layer PAS2 may be formed in a pattern so as to expose a portion of the surface of each of the first source/drain electrode SD1 and the second source/drain electrode SD2.

The first source/drain connection electrode NE1 and the second source/drain connection electrode NE2 may be formed on the second passivation layer PAS2. The first source/drain connection electrode NE1 may be electrically connected to the first source/drain electrode SD1 via one of the pair of via-holes, while the second source/drain connection electrode NE2 may be electrically connected to the second source/drain electrode SD2 via the other of the pair of via-holes.

The first light-emitting element ED1 may be disposed on the second passivation layer PAS2.

The first assembly electrode AE1, the second assembly electrode AE2, the clad electrode CDE, the first line electrode CE1, and the adhesive layer AD may be formed on the second passivation layer PAS2 so as to constitute the self-assembly structure.

The first assembly electrode AE1 and the second assembly electrode AE2 may be spaced apart from each other and may correspond to each of the plurality of first light-emitting elements ED1 assembled in a self-assembly process.

In this case, the first assembly electrode AE1 may be integrally formed with the second source/drain connection electrode NE2.

That is, the first assembly electrode AE1 may be referred to as the second source/drain connection electrode NE2.

The clad electrode layer CDE may be formed on the first assembly electrode AE1 and the second assembly electrode AE2. The clad electrode layer CDE may cover the first assembly electrode AE1 and the second assembly electrode AE2.

The clad electrode layer CDE may be also formed on the first source/drain connection electrode NE1. The clad electrode layer CDE may be disposed to cover the first source/drain connection electrode NE1.

The first light-emitting element ED1 may be disposed on the adhesive layer AD.

The first light-emitting element ED1 may include the semiconductor structure NSS, the first electrode E1, and the second electrode E2.

The first electrode E1 of the first light-emitting element ED1 may act as the first cathode electrode, and the second electrode E2 may act as the first anode electrode.

The first electrode E1 may be disposed on one surface of the first semiconductor layer where the active layer is not disposed, while the second electrode E2 may be disposed on one surface of the second semiconductor layer where the active layer is not disposed.

For example, the first electrode E1 may be formed to extend and on one surface of the first semiconductor layer and extend along and on a portion of a side surface of the first semiconductor layer.

The protective layer pattern PT may be formed to cover at least a portion of an outer surface of the first light-emitting element ED1.

The other surface of the first semiconductor layer opposite to one surface of the first semiconductor layer on which the active layer is disposed may contact the adhesive layer AD such that the first light-emitting element ED may be fixed to the adhesive layer AD.

The first line electrode CE1 disposed to surround the first electrode E1 may be formed on a side surface of the first light-emitting element ED1 and may contact and be electrically connected to the first electrode E1.

One side of the first line electrode CE1 may cover the clad electrode layer CDE, and may contact and be electrically connected to the clad electrode layer CDE.

In some implementations, the first electrode E1 of the first light-emitting element ED1 may be electrically connected to the first source/drain connection electrode NE1 via the first line electrode CE1.

In some implementations, the driving signal from the thin-film transistor TFT may be applied to the first electrode E1 as the first cathode electrode of the first light-emitting element ED1.

Further, the second line electrode CE2 may be formed on the first light-emitting element ED1, and may contact and be electrically connected to the second electrode E1.

The second overcoat layer OC2 may be formed to cover the first light-emitting element ED1.

The first line connection electrode 111, the first cathode connection electrode 115, and the second line electrode CE2 may be formed on the second overcoat layer OC2.

The first line connection electrode 111, the first cathode connection electrode 115, and the second line electrode CE2 may be made of the same material and may be disposed in the same layer.

Each of a pair of contact-holes may extend through the third passivation layer PAS3 and the second overcoat layer OC2 so as to expose a portion of the surface of the clad electrode layer CDE disposed on each of the first source/drain connection electrode NE1 and the second source/drain connection electrode NE2.

Further, the second overcoat layer OC2 may be formed not to cover a portion of the surface of the second electrode E2 of the first light-emitting element ED1 so as to be exposed.

The first line connection electrode 111 may be electrically connected to the first source/drain connection electrode NE1 via a portion of the clad electrode layer CDE exposed to the outside through one of the contact-holes.

Further, the first cathode connection electrode 115 may be electrically connected to the second source/drain connection electrode NE2 via a portion of the clad electrode layer CDE exposed to the outside through the other of the contact-holes.

Therefore, the first electrode E1 as the first cathode electrode of the first light-emitting element ED1, and the first cathode connection electrode 115 may be electrically connected to each other via the first source/drain connection electrode NE1.

The second line electrode CE2 may be electrically connected to the second electrode E2 of the first light-emitting element ED1 via a portion of the clad electrode layer CDE exposed to the outside through the contact-hole.

The second line electrode CE2 may be referred to the first anode connection electrode 113 electrically connected to the second electrode E2 as the first anode electrode.

In an example, the line substrate 20 may include the second substrate 200, the second light-emitting element ED2 disposed on the second substrate 200, and the various link lines LL.

The first assembly electrode AE1, the second assembly electrode AE2, the clad electrode CDE, the first line electrode CE1, and the adhesive layer AD may be disposed on the second substrate 200 to constitute the self-assembly structure.

In some implementations, the second light-emitting element ED2 including the first electrode E1, the semiconductor structure NSS, and the second electrode E2 may be fixed by the self-assembly structure formed on the second substrate 200.

In this case, the first electrode E1 of the second light-emitting element ED2 may act as the second cathode electrode, and the second electrode E2 thereof may act as the second anode electrode.

The link line LL may be formed on the second substrate 200.

The link line LL and the first assembly electrode AE1 and the second assembly electrode AE2 may be made of the same material and may be disposed in the same layer.

Further, the clad electrode layer CDE may be formed on the link line LL so as to cover the link line LL.

The passivation layer PAS may be formed on the self-assembly structure formed as described above and the link line LL. The overcoat layer OC may be formed to cover the passivation layer PAS and the second light-emitting element ED2.

The second line connection electrode 211, the second cathode connection electrode 215, and the second line electrode CE2 may be formed on the overcoat layer OC.

The second line connection electrode 211, the second cathode connection electrode 215, and the second line electrode CE2 may be made of the same material and may be disposed in the same layer.

A contact-hole may extend through the overcoat layer OC and the passivation layer PAS so that a portion of the surface of the clad electrode layer CDE disposed on the link line LL is exposed. A contact-hole extending through the overcoat layer OC and the passivation layer PAS may be formed to expose a portion of the surface of the clad electrode layer CDE disposed on the second assembly electrode AE2.

In some implementations, the second line connection electrode 211 may be electrically connected to the link line LL via a portion of the clad electrode layer CDE exposed to the outside through the contact-hole. The second cathode connection electrode 215 may be electrically connected to the second assembly electrode AE2 via a portion of the clad electrode layer CDE exposed to the outside through the contact-hole.

Further, the overcoat layer OC may be formed not to cover a portion of the surface of the second electrode E2 of the second light-emitting element ED2 so as to be exposed.

In some implementations, the second line electrode CE2 may be electrically connected to the second electrode E2 of the second light-emitting element ED2 exposed to the outside.

The line substrate 20 thus formed may be coupled to the panel unit 10 via the optical resin layer 330 interposed therebetween. The line substrate 20 and the panel unit 10 may be electrically connected to each other via the plurality of connection members 300.

The first connection member 310 may be disposed between the first line connection electrode 111 and the second line connection electrode 211, such that the first line connection electrode 111 and the second line connection electrode 211 may be electrically connected to each other via the first connection member 310.

In some implementations, the signal provided via the link line LL of the line substrate 20 may be applied to the first source/drain connection electrode NE1 and the first source/drain electrode SD1 via the second line connection electrode 211 and the first line connection electrode 111 of the thin-film transistor TFT.

In this case, the link line LL of the line substrate 20 may be the first data link line DL1_LL.

Further, the second connection member 320 may be disposed between the first cathode connection electrode 115 and the second cathode connection electrode 215, such that the first cathode connection electrode 115 and the second cathode connection electrode 215 may be electrically connected to each other via the second connection member 320.

The driving signal from the thin-film transistor TFT may be applied to the first electrode E1 as the second cathode electrode electrically connected to the second assembly electrode AE2 and the first line electrode CE1 of the second light-emitting element ED via the first cathode connection electrode 115 of the first light-emitting element ED1 and the second cathode connection electrode 215 of the second light-emitting element ED2.

The first light-emitting element ED1 and the second light-emitting element ED2 electrically connected to each other via the second connection member 320 may emit light of the same color.

Accordingly, the first cathode electrode of the first light-emitting element ED1 and the second cathode electrode of the second light-emitting element ED2 may share the driving signal provided from the thin-film transistor TFT disposed in the panel unit 10.

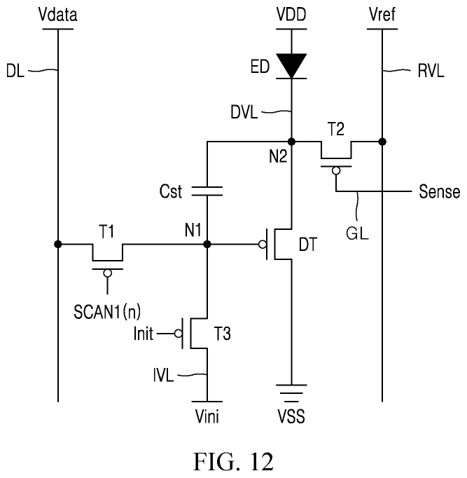

FIG. 12 is a circuit diagram of a case where the cathode electrode of the light-emitting element ED of the line substrate 20 and the cathode electrode of the light-emitting element ED of the panel unit 10 are electrically connected to each other and act as a common electrode according to an embodiment of the present disclosure.

FIG. 12 shows a 4T1C structure in which three thin-film transistors T1, T2, and T3 in addition to the driving thin-film transistor DT are disposed in a sub-pixel SP and one storage capacitor Cst is disposed in the sub-pixel by way of example. However, the present disclosure is not limited thereto.

The driving thin-film transistor DT may be electrically connected to and disposed between the light-emitting element ED and the low-potential driving voltage VSS.

The high-potential driving voltage VDD may be supplied via the driving voltage line DVL.

One electrode of the light-emitting element ED, for example, an anode electrode thereof may be electrically connected to the high-potential driving voltage VDD, while the other electrode of the light-emitting element ED, for example, a cathode electrode thereof may be electrically connected to the driving thin-film transistor DT.

The first thin-film transistor T1 may be electrically connected to and disposed between the data line DL and the first node N1. The first node N1 may be a gate node of a driving thin-film transistor DT.

The first thin-film transistor T1 may be controlled based on an n-th scan signal Scan1(n) supplied via the gate line GL.

The first thin-film transistor T1 may control application of the data voltage Vdata supplied via the data line DL to the first node N1 as the gate node of the driving thin-film transistor DT.

The second thin-film transistor T2 may be electrically connected to and disposed between the reference voltage line RVL and the second node N2.

The second node N2 may be a source node or a drain node of the driving thin-film transistor DT.

The second thin-film transistor T2 may be controlled based on a sense signal Sense supplied via the gate line GL.

The second thin-film transistor T2 may control application of the reference voltage Vref supplied via the reference voltage line RVL to the second node N2.

The third thin-film transistor T3 may be electrically connected to and disposed between the initialization voltage line IVL and the first node N1.

The third transistor T3 may be controlled based on an initialization signal Init supplied via the gate line GL.

The third transistor T3 may control application of the initialization voltage Vini to the first node N1 as the gate node of the driving thin-film transistor DT.

The storage capacitor Cst may be electrically connected to and disposed between the first node N1 and the second node N2. The storage capacitor Cst may maintain the data voltage Vdata for one frame period.

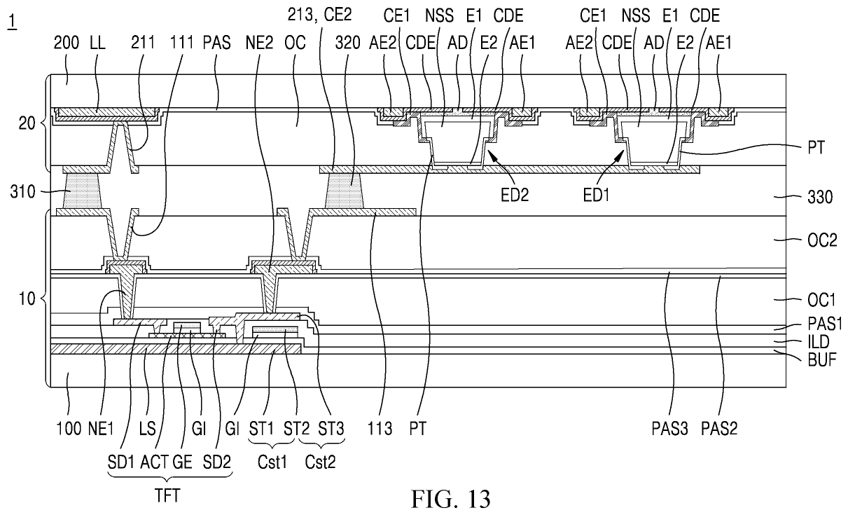

FIG. 13 is a detailed cross-sectional view of one sub-pixel SP in a state in which the line substrate 20 and the panel unit 10 are coupled to each other according to an embodiment of the present disclosure.

Descriptions about the display device 1 according to an embodiment of the present disclosure as described with reference to FIG. 13 duplicate with the description about the display device 1 as described with reference to FIG. 9 and FIG. 11 will be omitted. Following description will be based on differences therebetween.

The thin-film transistor TFT may be formed on the first substrate 100.

The first passivation layer PAS1 and the first overcoat layer OC1 may be stacked on the thin-film transistor TFT.

Each of a pair of via-holes or a pair of contact-holes extending thorough the first overcoat layer OC1 and the first passivation layer PAS1 may be formed so as to expose a portion of the surface of each of the first source/drain electrode SD1 and the second source/drain electrode SD2 of the thin-film transistor TFT.

The second passivation layer PAS2 including an insulating material may be disposed on the first overcoat layer OC1. The second passivation layer PAS2 may extend along and on an inner side surface of each of the pair of via-holes extending through the first overcoat layer OC1 and the first passivation layer PAS1.

However, the second passivation layer PAS2 may be formed in a pattern so as to expose a portion of the surface of each of the first source/drain electrode SD1 and the second source/drain electrode SD2.

The first source/drain connection electrode NE1 and the second source/drain connection electrode NE2 may be formed on the second passivation layer PAS2. The first source/drain connection electrode NE1 may be electrically connected to the first source/drain electrode SD1 via one of the pair of via-holes, while the second source/drain connection electrode NE2 may be electrically connected to the second source/drain electrode SD2 via the other of the pair of via-holes.

The clad electrode layer CDE may be formed on the first source/drain connection electrode NE1 and the second source/drain electrode SD2 so as to cover the first source/drain connection electrode NE1 and the second source/drain electrode SD2.

The third passivation layer PAS3 and the second overcoat layer OC2 may be formed on the clad electrode layer CDE covering the first source/drain connection electrode NE1 and the second source/drain electrode SD2.

The first line connection electrode 111 and the first anode connection electrode 113 may be formed on the second overcoat layer OC2.

The first line connection electrode 111 and the first anode connection electrode 113 may be made of the same material and may be disposed in the same layer.

Each of a pair of contact-holes may be formed to extend through the second overcoat layer OC2 and the third passivation layer PAS3 so as to expose a portion of the surface of the clad electrode layer CDE disposed on each of the first source/drain connection electrode NE1 and the second source/drain connection electrode NE2.

Accordingly, the first line connection electrode 111 may be electrically connected to the first source/drain connection electrode NE1 via a portion of the clad electrode layer CDE exposed to the outside through the contact-hole.

Further, the first anode connection electrode 113 may be electrically connected to the second source/drain connection electrode NE2 via a portion of the clad electrode layer CDE exposed to the outside through the contact-hole.

In an example, the line substrate 20 includes the second substrate 200, and the first light-emitting element ED1, the second light-emitting element ED2 and the various link lines LL disposed on the second substrate 200.

The first assembly electrode AE1, the second assembly electrode AE2, the clad electrode CDE, the first line electrode CE1, and the adhesive layer AD may be disposed on the second substrate 200 to constitute the self-assembly structure.

Accordingly, the first light-emitting element ED1 including the first electrode E1, the semiconductor structure NSS, and the second electrode E2, and the second light-emitting element ED2 including the first electrode E1, the semiconductor structure NSS, and the second electrode E2 may be fixed by the self-assembly structure formed on the second substrate 200.

Accordingly, a pair of self-assembly structures corresponding to one sub-pixel SP may be formed on the second substrate 200.

In this case, the first electrode E1 of the first light-emitting element ED1 may act as the first cathode electrode, and the second electrode E2 thereof may act as the first anode electrode.

Further, the first electrode E1 of the second light-emitting element ED2 may act as the second cathode electrode, and the second electrode E2 thereof may act as the second anode electrode.

The first light-emitting element ED1 may act as a main light-emitting element, and the second light-emitting element ED2 may act as a redundant light-emitting element.

Accordingly, both the main light-emitting element and the redundant light-emitting element may be disposed on the line substrate 20.

The link line LL may be formed on the second substrate 200.

The link line LL and the first assembly electrode AE1 and the second assembly electrode AE2 may be made of the same material and may be disposed in the same layer.

Further, the clad electrode layer CDE may be formed on the link line LL so as to cover the link line LL.

The passivation layer PAS may be formed on the self-assembly structure thus formed and the link line LL. The overcoat layer OC may be formed to cover the passivation layer PAS and the second light-emitting element ED2.

The second line connection electrode 211 and the second anode connection electrode 213 may be formed on the overcoat layer OC.

The second line connection electrode 211 and the second anode connection electrode 213 may be made of the same material and may be disposed in the same layer.

A contact-hole may extend through the overcoat layer OC and the passivation layer PAS so that a portion of the surface of the clad electrode layer CDE disposed on the link line LL is exposed.

Accordingly, the second line connection electrode 211 may be electrically connected to the link line LL via a portion of the clad electrode layer CDE exposed to the outside through the contact-hole.

Further, the overcoat layer OC may be formed not to cover a portion of the surface of the second electrode E2 of the first light-emitting element ED1 and a portion of the surface of the second electrode E2 of the second light-emitting element ED2 so as to be exposed.

Accordingly, the second anode connection electrode 213 may be electrically connected the second electrode E2 of the first light-emitting element ED1 and the second electrode E2 of the second light-emitting element ED2 exposed to the outside.

That is, the second electrode E2 of the first light-emitting element ED1 and the second electrode E2 of the second light-emitting element ED2 may be coplanar with each other, and may be electrically connected to each other via one second anode connection electrode 213.

The line substrate 20 thus formed may be coupled to the panel unit 10 via the optical resin layer 330 interposed therebetween. The line substrate 20 and the panel unit 10 may be electrically connected to each other via the plurality of connection members 300.

The first connection member 310 may be disposed between the first line connection electrode 111 and the second line connection electrode 211, such that the first line connection electrode 111 and the second line connection electrode 211 may be electrically connected to each other via the first connection member 310.

Accordingly, the signal provided via the link line LL of the line substrate 20 may be applied to the first source/drain connection electrode NE1 and the first source/drain electrode SD1 of the thin-film transistor TFT via the second line connection electrode 211 and the first line connection electrode 111.

In this case, the link line LL of the line substrate 20 may be the first data link line DL1_LL.

Further, the second connection member 320 may be disposed between the first anode connection electrode 113 and the second anode connection electrode 213, such that the first anode connection electrode 113 and the second anode connection electrode 213 may be electrically connected to each other via the second connection member 320.

Thus, the driving signal from the thin-film transistor TFT may be transmitted to the second anode connection electrode 213 via the first anode connection electrode 113 electrically connected to the first source/drain connection electrode NE1.

The driving signal from the thin-film transistor TFT transmitted to the second anode connection electrode 213 in this way may be applied to the second electrode E2 as the anode electrode of the first light-emitting element ED1, and the second electrode E2 as the anode electrode of the second light-emitting element ED2, so that the first light-emitting element ED1 and the second light-emitting element ED2 may operate.

That is, the second connection member 320 may electrically connect the first light-emitting element ED1 and the second light-emitting element ED2 disposed on the line substrate 20 to the thin-film transistor TFT disposed on the panel unit 10.

The first light-emitting element ED1 and the second light-emitting element ED2 electrically connected to each other via the second anode connection electrode 213 may emit light of the same color.

In some implementations, the first anode electrode of the first light-emitting element ED1 and the second anode electrode of the second light-emitting element ED2 may share the driving signal provided from the thin-film transistor TFT disposed in the panel unit 10.

As described above, in the display device 1 according to an embodiment of the present disclosure, the main light-emitting element and the redundant light-emitting element may be disposed on the line substrate 20 separate from the panel unit 10 on which the thin-film transistor TFT is disposed. Thus, after inspecting whether the main light-emitting element is defective, the redundant light-emitting element may be additionally disposed based on the inspection result.

In some implementations, the redundant light-emitting element may be disposed only in the sub-pixel where the defective main light-emitting element is disposed, while the redundant light-emitting element is not required to be disposed in the sub-pixel where the normal main light-emitting element is disposed. Thus, an unnecessary redundant light-emitting element need not to be disposed, such that a great cost reduction effect may be obtained.

Further, although not shown in the drawings, the second light-emitting element ED2 as the redundant light-emitting element disposed on the line substrate 20 may receive a separate driving signal for driving the second light-emitting element ED2 from the thin-film transistor TFT disposed on the line substrate 20.

That is, the thin-film transistor TFT disposed on the panel unit 10 may apply a driving signal to the first light-emitting element ED1, while the thin-film transistor TFT disposed on the line substrate 20 may apply a driving signal to the second light-emitting element ED2.

A display device according to an embodiment of the present disclosure described above may be described as follows.

A first aspect of the present disclosure provides a display device comprising: a plurality of panel units, each including a plurality of first light-emitting elements; and a line substrate on which a plurality of second light-emitting elements are disposed, wherein the plurality of panel units are coupled to the line substrate in a tiling manner.

A second aspect of the present disclosure provides a display device comprising: a line substrate including a plurality of first light-emitting elements and a plurality of second light-emitting elements; and a plurality of panel units, each panel unit including a thin-film transistor for applying a driving signal to each of the plurality of first light-emitting elements and each of the plurality of second light-emitting elements, wherein the plurality of panel units are coupled to the line substrate in a tiling manner.

In one implementation of the first and second aspects, the second light-emitting element acts as a redundant light-emitting element.

In one implementation of the first and second aspects, a combination of the first light-emitting element and the second light-emitting element emitting light of the same color constitutes one sub-pixel.

In one implementation of the first and second aspects, the first light-emitting element includes a normal light-emitting element capable of emitting light and a defective light-emitting element incapable of emitting light, wherein the sub-pixel including the defective light-emitting element includes the second light-emitting element, wherein the sub-pixel including the normal light-emitting element is free of the second light-emitting element.

In one implementation of the first and second aspects, a plurality of link lines are disposed on the line substrate, wherein a circuit film is connected to one side of the line substrate, wherein a plurality of signal lines are disposed in the panel unit, wherein a signal provided via the circuit film is applied to a corresponding signal line via a corresponding link line.

In one implementation of the first aspect, a thin-film transistor for applying a driving signal to the first light-emitting element is disposed in the panel unit, wherein the thin-film transistor applies the driving signal to the second light-emitting element, wherein the first and second light-emitting elements emit light of the same color.

In one implementation of the first aspect, a thin-film transistor for applying a driving signal to the first light-emitting element is disposed on the panel unit, wherein a thin-film transistor for applying a driving signal to the second light-emitting element is disposed on the line substrate.

A third aspect of the present disclosure provides a display device comprising: a plurality of panel units, wherein each panel unit includes a plurality of signal lines, a plurality of first light-emitting elements, and a thin-film transistor for applying a driving signal to the first light-emitting elements; a line substrate on which a plurality of link lines and a plurality of second light-emitting elements are disposed; and a plurality of first connection members and a plurality of second connection members disposed between the line substrate and the panel units, wherein the first connection member electrically connects the link line and the signal line to each other, wherein the second connection member electrically connects the second light-emitting element and the thin-film transistor to each other.

In one implementation of the third aspect, a circuit film electrically connected to the link line is disposed on one side of the line substrate, wherein a signal provided via the circuit film is applied to a corresponding signal line via a corresponding link line.

In one implementation of the third aspect, the first light-emitting element and the second light-emitting element electrically connected to each other via the second connection member emit light of the same color.

In one implementation of the third aspect, each panel unit includes a plurality of sub-pixels, wherein each of the first light-emitting elements is disposed in each of the sub-pixels, wherein each of the second light-emitting elements is selectively present or absent in each of the sub-pixels.

In one implementation of the third aspect, the second light-emitting element is present in the sub-pixel where a defective first light-emitting element is disposed, wherein the second light-emitting element is absent in the sub-pixel in which a normal first light-emitting element is disposed.

In one implementation of the third aspect, the first light-emitting element includes a first anode electrode and a first cathode electrode, wherein the second light-emitting element includes a second anode electrode and a second cathode electrode, wherein the second anode electrode is electrically connected to the first anode electrode such that the second anode electrode shares the driving signal applied to the first anode electrode.

In one implementation of the third aspect, each panel unit further includes a first anode connection electrode electrically connecting the thin-film transistor and the first anode electrode to each other, wherein a second anode connection electrode electrically connected to the second anode electrode is further disposed on the line substrate, wherein the second connection member electrically connects the first anode connection electrode and the second anode connection electrode to each other.

In one implementation of the third aspect, the first light-emitting element includes a first anode electrode and a first cathode electrode, wherein the second light-emitting element includes a second anode electrode and a second cathode electrode, wherein the second cathode electrode is electrically connected to the first cathode electrode so as to share a driving signal applied to the first cathode electrode.

In one implementation of the third aspect, each panel unit further includes a first cathode connection electrode electrically connected to the thin-film transistor, wherein a second cathode connection electrode electrically connected to the second cathode electrode is further disposed on the line substrate, wherein the second connection member electrically connects the first cathode connection electrode and the second cathode connection electrode to each other.

A fourth aspect of the present disclosure provides a display device comprising: a line substrate on which a plurality of link lines, a plurality of first light-emitting elements, and a plurality of second light-emitting elements are disposed; a plurality of panel units, wherein each panel unit includes a plurality of signal lines and a thin-film transistor for applying a driving signal to each of the first light-emitting element and the second light-emitting element; and a plurality of first connection members and a plurality of second connection members disposed between the line substrate and the panel units, wherein the first connection member electrically connects the link line and the signal line to each other, wherein the second connection member electrically connects the first light-emitting element and the second light-emitting element to the thin-film transistor.

In one implementation of the fourth aspect, the second light-emitting element acts as a redundant light-emitting element.

In one implementation of the fourth aspect, a circuit film electrically connected to the link line is disposed on one side of the line substrate, wherein a signal provided via the circuit film is applied to a corresponding signal line via a corresponding link line.

Described embodiments of the subject matter can include one or more features, alone or in combination. For example, in a first embodiment, a display device includes: a body including a first light-emitting element; and a substrate on which a plurality of second light-emitting elements are disposed. The body is coupled to the substrate through a connection structure.

The foregoing and other described embodiments can each include one or more of the following features:

A first feature, combinable with any of the previous or the following features, specifies that each second light-emitting element of the plurality of second light-emitting elements is configured as a redundant light-emitting element.

A second feature, combinable with any of the previous or the following features, specifies that a first light-emitting element of the plurality of first light-emitting elements and an adjacent second light-emitting element of the plurality of second light-emitting elements are configured to emit light of a same color and constitute a same sub-pixel.

A third feature, combinable with any of the previous or the following features, specifies that the sub-pixel includes a transmissive area.

A fourth feature, combinable with any of the previous or the following features, specifies that the plurality of first light-emitting elements include normal light-emitting elements capable of emitting light and one or more defective light-emitting element incapable of emitting light. The first light-emitting element in the sub-pixel including the second light-emitting element is a defective light-emitting element. A sub-pixel including a normal light-emitting element of the normal light-emitting elements is free of a second light-emitting element.

A fifth feature, combinable with any of the previous or the following features, specifies that the display device includes a circuit film connected to a side of the substrate. A plurality of link lines are disposed on the substrate. A plurality of signal lines are disposed in each panel unit of the plurality of panel units. A link line of the plurality of link lines connects the circuit film and a signal line of the plurality of signal lines.

A sixth feature, combinable with any of the previous or the following features, specifies that each panel unit of the plurality of panel units includes a thin-film transistor, the thin-film transistor configured to apply a driving signal to a first light-emitting element of the plurality of first light-emitting elements disposed in the panel unit. The thin-film transistor is also configured to apply the driving signal to a second light-emitting element of the plurality of second light-emitting element, and wherein the first light-emitting element and the second light-emitting element are configured to emit light of a same color.

A seventh feature, combinable with any of the previous or the following features, specifies that each panel unit of the plurality of panel units includes a thin-film transistor configured to apply a driving signal to a first light-emitting element disposed on the panel unit. The substrate includes a thin-film transistor configured to apply a driving signal to a second light-emitting element disposed on the substrate.

In a second embodiment, a display device includes: a substrate on which a plurality of first light-emitting elements and a plurality of second light-emitting elements are disposed; and a plurality of panel units, each panel unit including a thin-film transistor configured to apply a driving signal to one or more of a first light-emitting element of the plurality of first light-emitting elements or a second light-emitting element of the plurality of second light-emitting elements. The plurality of panel units are coupled to the substrate in a tiling manner.

In a third embodiment, a display device includes: a substrate including a plurality of link lines, a plurality of first light-emitting elements, and a plurality of second light-emitting elements; a plurality of panel units, each panel unit having a plurality of signal lines and a thin-film transistor configured to apply a driving signal to a first light-emitting element of the plurality of first light-emitting elements and a second light-emitting element of the plurality of second light-emitting elements; and a plurality of first connection members and a plurality of second connection members disposed between the substrate and the panel units. The plurality of first connection members each electrically connects a link line of the plurality of link lines to a signal line of the plurality of signal lines. The plurality of second connection members each electrically connects a first light-emitting element of the plurality of first light-emitting elements or a second light-emitting element of the plurality of second light-emitting elements to a thin-film transistor.

An eighth feature, combinable with any of the previous or the following features, specifies that the second light-emitting element is configured as a redundant light-emitting element.

A ninth feature, combinable with any of the previous or the following features, specifies that the display device includes a circuit film electrically connected to the link line and disposed on a side of the substrate. The circuit film is configured to send to the signal line via the link line.

Although the embodiments of the present disclosure have been described in more detail with reference to the accompanying drawings, the present disclosure is not necessarily limited to these embodiments, and may be modified in a various manner within the scope of the technical spirit of the present disclosure. Accordingly, the embodiments as disclosed in the present disclosure are intended to describe rather than limit the technical idea of the present disclosure, and the scope of the technical idea of the present disclosure is not limited by these embodiments. Therefore, it should be understood that the embodiments described above are not restrictive but illustrative in all respects.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display device, comprising:
a substrate;
a first sub-pixel on the substrate, the first subpixel having a first light emitting element and a second light emitting element each configured to emit light of a first color, the first and second light emitting element coupled to a same first driving transistor; and
a second sub-pixel on the substrate, the second subpixel having a third light emitting element and a fourth light emitting element each configured to emit light of a second color different from the first color.

2. The display device of claim 1, wherein the third light emitting element is coupled to a second driving transistor, and the fourth light emitting element is coupled to a third driving transistor different from the second driving transistor.

3. The display device of claim 1, wherein a first cathode of the first light emitting element and a second cathode of the second light emitting element are connected to each other.

4. The display device of claim 1, wherein a first anode of the first light emitting element and a second anode of the second light emitting element are connected to each other.

5. The display device of claim 1, wherein the first light emitting element is defective and the second light emitting element is in a functioning condition.

6. The display device of claim 1, further comprising a third subpixel on the substrate, the third subpixel including only one fifth light emitting element configured to emit light of a third color different from the first color and the second color.

7. The display device of claim 1, wherein the first light emitting element includes a cathode electrode, an anode electrode, a semiconductor structure between the cathode electrode and the anode electrode, and a protection layer on a sidewall of the semiconductor structure.

8. The display device of claim 7, comprising a connection electrode connected to the anode electrode, the connection electrode overlapping with the protection layer.

9. The display device of claim 7, comprising a connection electrode connected to the cathode electrode, the connection electrode overlapping with the protection layer.

10. The display device of claim 8, comprising an interconnection structure connected to the cathode electrode, the interconnection structure at least partially on a same level as the connection electrode connected to the anode electrode.

11. The display device of claim 7, comprising an adhesive layer between the semiconductor structure and the substrate.

12. The display device of claim 11, wherein the adhesive layer and the protection layer are separated from one another.

13. The display device of claim 1, wherein the first subpixel includes a transmissive area.

14. The display device of claim 1, wherein the first light emitting element and the second light emitting element of the first subpixel are on a same level.

15. The display device of claim 7, wherein the semiconductor structure includes a staggered shape in a cross-sectional view.

16. A display device, comprising:
a plurality of panel units, wherein each panel unit includes a plurality of signal lines, a plurality of first light-emitting elements, and a thin-film transistor configured to apply a driving signal to the plurality of first light-emitting elements;
a substrate including a plurality of link lines and a plurality of second light-emitting elements; and
a plurality of first connection members and a plurality of second connection members disposed between the substrate and the panel units,
wherein a first connection member of the plurality of first connection members electrically connects a link line of the plurality of link lines to a signal line of the plurality of signal lines,
wherein a second connection member of the plurality of second connection members electrically connects a second light-emitting element of the plurality of second light-emitting elements to a thin-film transistor.

17. The display device of claim 16, comprising a circuit film electrically connected to the link line on one side of the substrate,
wherein the circuit film is configured to send a signal to the signal line via the link line.

18. The display device of claim 16, wherein a first light-emitting element corresponding to the thin-film transistor connected to the second connection member and the second light-emitting element connected to the second connection member are configured to emit light of a same color.

19. The display device of claim 16, wherein each panel unit of the plurality of panel units includes a plurality of sub-pixels,
wherein each of the plurality of first light-emitting elements is disposed in a subpixel of the plurality of sub-pixels,
wherein each of the second light-emitting elements is selectively present in a sub-pixel of the plurality of subpixels, and at least some of the plurality of sub-pixels are free of any second light-emitting element of the plurality of second light-emitting elements.

20. The display device of claim 19, wherein the second light-emitting element is present in the sub-pixel where a defective first light-emitting element is disposed,
wherein the second light-emitting element is absent in a sub-pixel in which a normal first light-emitting element is disposed.

21. The display device of claim 16, wherein the first light-emitting element includes a first anode electrode and a first cathode electrode, the first anode electrode configured to receive the driving signal,
wherein the second light-emitting element includes a second anode electrode and a second cathode electrode,
wherein the second anode electrode is electrically connected to the first anode electrode.

22. The display device of claim 21, wherein each panel unit further includes a first anode connection electrode electrically connecting the thin-film transistor and the first anode electrode to each other,
wherein the substrate further includes a second anode connection electrode electrically connected to the second anode electrode,
wherein the second connection member electrically connects the first anode connection electrode and the second anode connection electrode to each other.

23. The display device of claim 16, wherein the first light-emitting element includes a first anode electrode and a first cathode electrode, the first cathode electrode configured to receive the driving signal,
wherein the second light-emitting element includes a second anode electrode and a second cathode electrode,
wherein the second cathode electrode is electrically connected to the first cathode electrode.

24. The display device of claim 23, wherein each panel unit further includes a first cathode connection electrode electrically connected to the thin-film transistor,
wherein the substrate further includes a second cathode connection electrode electrically connected to the second cathode electrode,
wherein the second connection member electrically connects the first cathode connection electrode and the second cathode connection electrode to each other.

25. A display device comprising:
a first body, the first body including a substrate layer and one or more light emitting elements on the substrate layer;
a plurality of panel units each coupled to the first body in a first direction, the plurality of panel units positioned with respect to one another in a second direction that traverses the first direction, each panel unit of the plurality of panel units including a thin-film transistor,
wherein a first light-emitting element of the one or more light emitting elements of the first body is electrically connected to a first thin-film transistor of a first panel unit of the plurality of panel units.

26. The display device of claim 25, wherein the first panel unit includes a second light-emitting element in a same subpixel as the first light-emitting element, and the second light-emitting element is defective.

27. The display device of claim 26, wherein the first light-emitting element and the second light-emitting element are configured to emit light of a same color.

28. The display device of claim 26, comprising a connection structure that electrically connects between a terminal of the first light-emitting element and a terminal of the second light-emitting element.

29. The display device of claim 25, wherein the first body includes a link line and the first panel unit includes a signal line, and
the display device further comprises a connection structure that electrically connects between the link line and the signal line.
